(19) United States
(12) Patent Application Publication
(10) Pub. No.: US 2025/0081751 A1
(43) Pub. Date: Mar. 6, 2025

(54) DISPLAY DEVICE, APPARATUS FOR MANUFACTURING THE SAME, AND WEARABLE ELECTRONIC DEVICE

(71) Applicant: Samsung Display Co., LTD., Yongin-si (KR)

(72) Inventor: Seok Hyun LIM, Yongin-si (KR)

(21) Appl. No.: 18/816,993

(22) Filed: Aug. 27, 2024

(30) Foreign Application Priority Data
Aug. 31, 2023 (KR) 10-2023-0115611

(51) Int. Cl. H10K 59/122; G02B 27/01; H10K 50/19; H10K 59/35

(52) U.S. Cl. CPC H10K 59/122; G02B 27/0172; H10K 50/19; H10K 59/35

(57) ABSTRACT

A display device includes a first sub-pixel, and a second sub-pixel located adjacent to the first sub-pixel. Each of the first and the second sub-pixels may include: a first electrode; a pixel defining layer on the first electrode; a first emission component on the pixel defining layer and configured to emit light; a first intermediate layer on the first emission component; a second emission component on the first intermediate layer and configured to emit light; and a second electrode on the second emission component. A trench may be formed by recessing at least a portion of the pixel defining layer in a boundary area between the first sub-pixel and the second sub-pixel. The first intermediate layer may be interrupted over the trench. The second emission component may completely cover the first intermediate layer over the trench.

### CROSS-REFERENCE TO RELATED APPLICATION

The present application claims priority to and the benefit of Korean patent application number 10-2023-0115611, filed on Aug. 31, 2023, in the Korean Intellectual Property Office, the entire content of which is incorporated by reference herein.

### BACKGROUND

### 1. Field

Various embodiments of the present disclosure relate to a display device, an apparatus for fabricating the display device, and a wearable electronic device.

### 2. Description of the Related Art

Recently, as interest in information display and/or display devices increases, research and development on such display devices have been continuously conducted or pursued.

### SUMMARY

Aspects of one or more embodiments of the present disclosure are directed toward a display device with improved reliability, an apparatus for fabricating the display device, and a wearable electronic device.

One or more embodiments of the present disclosure may provide a display device, including a first sub-pixel; and a second sub-pixel located adjacent to the first sub-pixel. The each of the first and the second sub-pixels may include: a first electrode; a pixel defining layer on the first electrode; a first emission component on the pixel defining layer and configured to emit light; a first intermediate layer on the first emission component; a second emission component on the first intermediate layer and configured to emit light; and a second electrode on the second emission component. A trench may be formed by recessing at least a portion of the pixel defining layer in a boundary area between the first sub-pixel and the second sub-pixel. The first intermediate layer may be interrupted over the trench. The second emission component may completely cover the first intermediate layer over the trench.

The first intermediate layer may include a material having higher charge conductivity than that of each of the first and second emission components and has conductive properties.

The first intermediate layer and the second electrode may be electrically insulated from each other.

The pixel defining layer may include a first surface and a second surface facing each other with the trench interposed therebetween, and a third surface connecting the first surface to the second surface. The first surface may include a first sidewall of the trench, the second surface may include a second sidewall of the trench, and the third surface may include a bottom surface of the trench.

An end of the second emission component on the first and second sidewalls may be closer to the bottom surface than is an end of the first intermediate layer to the bottom surface, and the second emission component may completely cover the first intermediate layer on the first and second sidewalls.

The first emission component may be interrupted in the trench. The second emission component of the first sub-pixel and the second emission component of the second sub-pixel may be connected to each other.

Each of the first and the second sub-pixels may further include: a third emission component located between the first electrode and the first emission component, and configured to emit light; and a second intermediate layer located between the third emission component and the first emission component. The second intermediate layer may be interrupted over the trench. The first emission component may completely cover the second intermediate layer over the trench.

The second intermediate layer may include a material having higher charge conductivity than that of each of the first emission component, the second emission component, and the third emission component, and has conductive properties. The first intermediate layer, the second intermediate layer, and the second electrode may be electrically insulated from each other.

On the first and the second sidewalls, an end of the second emission component may be closer to the bottom surface than is an end of the first intermediate layer to the bottom surface, and an end of the first emission component may be closer to the bottom surface than is an end of the second intermediate layer to the bottom surface. On the first and the second sidewalls, the second emission component may completely cover the first intermediate layer, and the first emission component may completely cover the second intermediate layer.

The third emission component and the first emission component may be interrupted in the trench. The second emission component of the first sub-pixel and the second emission component of the second sub-pixel may be connected to each other.

The trench may include a void enclosed by the first emission component, the second emission component, and the third emission component.

A distance between the first intermediate layer and the second electrode may be greater than a distance between the first intermediate layer and the second intermediate layer.

The first emission component may include a first hole transport component, a first emission layer, and a first electron transport component. The second emission component may include a second hole transport component, a second emission layer, and a second electron transport component. The third emission component may include a third hole transport component, a third emission layer, and a third electron transport component.

Each of the first and second sub-pixels may further include: a substrate under the first electrode; a pixel circuit layer located between the substrate and the first electrode, and including at least one transistor electrically connected to the first electrode; a planarization layer located between the pixel circuit layer and the first electrode; and an encapsulation layer on the second electrode. The trench may pass through at least a portion of the planarization layer.

One or more embodiments of the present disclosure may provide an apparatus, the apparatus being for fabricating a display device including a first sub-pixel and a second sub-pixel, each of the first sub-pixel and the second sub-pixel including a pixel defining layer, a first emission component, a first intermediate layer, a second emission component, and a second electrode that are successively located on a first electrode, and a trench formed by recessing a portion of the pixel defining layer in a boundary area between the first and the second sub-pixels. The apparatus may include: a first deposition chamber configured to form the first intermediate layer on the pixel defining layer; and second deposition chamber configured to form each of the first and the second emission components on the pixel defining layer.

The first deposition chamber may include a first nozzle component configured to spray deposition material of the first intermediate layer, and a first angle-limit component connected to the first nozzle component and configured to limit an incident angle of the deposition material. The second deposition chamber may include a second nozzle component configured to spray deposition material of each of the first and the second emission components, and a second angle-limit component connected to the second nozzle component and configured to limit an incident angle of the deposition material.

The deposition material of the first intermediate layer and the deposition material of each of the first and the second emission components may be incident on the pixel defining layer at different incident angles.

The first intermediate layer may include a material having higher charge conductivity than that of each of the first and second emission components and has conductive properties.

The first angle-limit component may be configured to enable the deposition material of the first intermediate layer to be incident on the pixel defining layer at a low incident angle. The second angle-limit component may be configured to enable the deposition material of each of the first and second emission components to be incident on the pixel defining layer at a high incident angle.

Each of the first and the second sub-pixels may further include a second intermediate layer located between the second emission component and the second electrode and having conductive properties, and a third emission component located between the second intermediate layer and the second electrode. The first deposition chamber may be configured to spray deposition material of the second intermediate layer onto the second emission component, and the second deposition chamber may be configured to spray deposition material of the third emission component onto the second intermediate layer.

The deposition material of the second intermediate layer and the deposition material of the third emission component may be incident at different incident angles.

One or more embodiments of the present disclosure may provide a wearable electronic device including: a display panel; and a lens located on the display panel. The display panel may include a first sub-pixel, and a second sub-pixel located adjacent to the first sub-pixel. Each of the first and the second sub-pixels may include: a first electrode; a pixel defining layer on the first electrode; a first emission component on the pixel defining layer and configured to emit light; a first intermediate layer on the first emission component; a second emission component on the first intermediate layer and configured to emit light; and a second electrode on the second emission component.

A trench may be formed by recessing at least a portion of the pixel defining layer in a boundary area between the first sub-pixel and the second sub-pixel. The first intermediate layer may be interrupted over the trench. The second emission component may completely cover the first intermediate layer over the trench.

Each of the first and the second sub-pixels may include: a third emission component between the first electrode and the first emission component, and configured to emit light; and a second intermediate layer between the third emission component and the first emission component. The third emission component and the second intermediate layer may be interrupted over the trench. The first emission component may completely cover the second intermediate layer over the trench.

### BRIEF DESCRIPTION OF THE DRAWINGS

FIG. 1 is a schematic plan view illustrating a display device in accordance with one or more embodiments.

FIG. 2 is a schematic exploded perspective view illustrating a portion of a display panel of FIG. 1.

FIG. 3 is a schematic plan view illustrating one or more embodiments of one of the pixels of FIG. 2.

FIG. 4 is a schematic cross-sectional view taken along the line I-I′ of FIG. 3.

FIG. 5 is a schematic cross-sectional view illustrating one or more embodiments of an emission structure included in one of first to third light emitting elements of FIG. 4.

FIG. 6 is a schematic cross-sectional view illustrating an embodiment of an emission structure included in one of the first to third light emitting elements of FIG. 4.

FIGS. 7A-7C are schematic sectional views each showing an enlargement of a portion of the display device of FIG. 4.

FIG. 8 is a schematic view illustrating an enlargement of portion EA of FIG. 7A.

FIG. 9 is a schematic view illustrating one or more embodiments of an apparatus for fabricating the display device.

FIG. 10 is a schematic view illustrating a first deposition source of FIG. 9.

FIG. 11 is a schematic view illustrating a second deposition source of FIG. 9.

FIG. 12 illustrates simulation results of deposition appearance based on incident angles of components of the emission structure disposed on a trench.

FIG. 13 is a schematic block diagram illustrating one or more embodiments of a display system.

FIG. 14 is a schematic perspective view illustrating an application example of the display system of FIG. 13.

FIG. 15 is a schematic view illustrating a head mounted display of FIG. 14 that is worn on a user.

### DETAILED DESCRIPTION

Hereinafter, one or more embodiments of the present disclosure will be described in more detail with reference to the attached drawings. In the following description, only parts required for understanding of operations in accordance with the present disclosure will be described, and explanation of the other parts will not be provided because they may make the gist of the present disclosure unclear. Accordingly, the present disclosure is not limited to embodiments set forth herein but may be embodied in other types (kinds). Rather, these embodiments are provided so that the present disclosure will be thorough and complete, and will fully convey the technical spirit of the present disclosure to those skilled in the art.

It will be understood that in case that an element is referred to as being “coupled” or “connected” to another element, it can be directly coupled or connected to the other element or intervening elements may be present therebetween. The terminology utilized herein is for the purpose of describing particular embodiments only and is not intended to be limiting. In the present disclosure, in case that an element is referred to as “comprising” or “including” a component, it does not preclude another component but may further include other components unless the context clearly indicates otherwise. For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and B” may include A, B, or A and B. As utilized herein, the term “and/or” includes any and all combinations of one or more of the associated listed items. For example, the expression such as “A and/or B” may include A, B, or A and B. Further, the of “may” when describing embodiments of the present disclosure refers to “one or more embodiments of the present disclosure”.

Although the terms “first,” “second,” etc. may be utilized herein to describe one or more suitable types (kinds) of elements, these elements should not be limited by these terms. These terms are utilized to distinguish one element from another element. Thus, a first element discussed could be termed a second element without departing from the teachings of the present disclosure.

Spatially relative terms, such as “beneath,” “below,” “under,” “lower,” “above,” “upper,” “over,” “higher,” “side” (e.g., as in “sidewall”), and/or the like, may be utilized herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” can encompass both (e.g., simultaneously) an orientation of above and below. Furthermore, the device may be otherwise oriented (e.g., rotated 90 degrees or at other orientations), and, as such, the spatially relative descriptors utilized herein interpreted accordingly.

Various embodiments will be described with reference to diagrams illustrating idealized embodiments. As such, variations from the shapes of the illustrations as a result, for example, of manufacturing techniques and/or tolerances, are to be expected. Therefore, embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting.

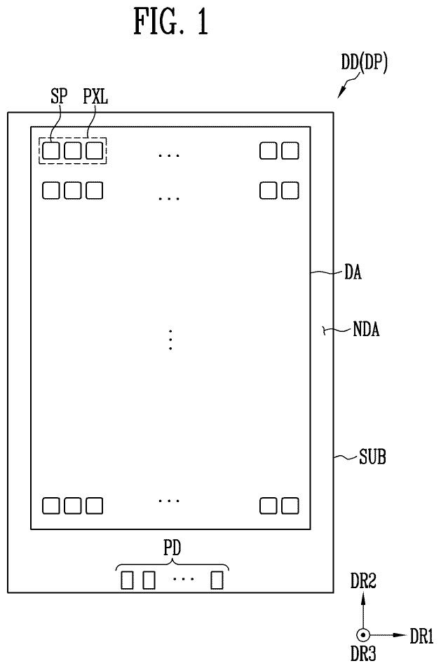

FIG. 1 is a schematic plan view illustrating a display device DD in accordance with one or more embodiments. In FIG. 1, for the ease of explanation, there is schematically illustrated the structure of the display device DD, for example, a display panel DP provided in the display device DD, centered on or at a display area DA in which an image is displayed.

Referring to FIG. 1, the display panel DP may include a display area DA and a non-display area NDA around an edge or periphery of the display area DA. The display panel DP may display an image through the display area DA. The non-display area NDA may be disposed around the display area DA.

The display panel DP may include a substrate SUB, and sub-pixels SP, and pads PD.

In the case where the display panel DP is utilized as a display screen for a head mounted display (HMD), a virtual reality (VR) device, a mixed reality (MR) device, an augmented reality (AR) device, and/or the like, the display panel DP may be positioned very or substantially close to the eyes of the user. In this case, relatively high-density sub-pixels SP may be required. The substrate SUB may be formed of a silicon substrate (or a silicon wafer) to increase the density of the sub-pixels S, but is not limited thereto. In the silicon substrate, the sub-pixels SP and/or the display panel DP may be formed on the substrate SUB. The display device DD including the display panel DP formed on the substrate SUB that is a silicon substrate may be referred to as an organic light emitting diode (OLED) on Silicon (OLEDoS) display device.

The sub-pixels SP may be disposed in the display area DA on the substrate SUB. The sub-pixels SP may be arranged in the form of a matrix in a first direction DR1 and a second direction DR2 crossing with the first direction DR1, but the arrangement of the sub-pixels SP is not limited thereto. For example, the sub-pixels SP may be arranged along rows and columns of a matrix along the first direction DR1 and the second direction DR2. For example, the sub-pixels SP may be arranged in a zigzag pattern along the first direction DR1 and the second direction DR2. The first direction DR1 may refer to a row direction, and the second direction DR2 may refer to a column direction.

Two or more sub-pixels SP selected from among the plurality of sub-pixels SP may form one pixel PXL.

Components for controlling the sub-pixels SP may be disposed on the substrate SUB in the non-display area NDA. For example, lines electrically connected to the sub-pixels SP may be disposed in the non-display area NDA. The lines may include, for example, gate lines, date lines, and/or the like.

A driver electrically connected to the sub-pixels SP to drive the sub-pixels SP may be disposed (or integrated) in the non-display area NDA of the display panel DP. The pads PD may be disposed on the substrate SUB in the non-display area NDA. The pads PD may be electrically connected to the sub-pixels SP through the lines. For example, the pads PD may be electrically connected to the sub-pixels SP through the data lines.

The pads PD may interface the display panel DP with other components of the display device DD. In one or more embodiments, voltages and signals required for the operation of the components included in the display panel DP may be provided through the pads PD from the driver (or a driver integrated circuit). For example, the data lines may be electrically connected to the driver through the pads PD.

In one or more embodiments, a circuit board may be electrically connected to the pads PD by a conductive adhesive component such as an anisotropic conductive film. The circuit board may be a flexible circuit board or flexible film that is made of flexible material. The driver may be mounted on the circuit board and may be electrically connected to the pads PD.

In one or more embodiments, the display area DA may have one or more suitable shapes. The display area DA may have a closed-loop shape, including linear and/or curved sides. For example, the display area DA may have shapes such as polygons, circles, semicircles, ellipses, and/or the like, but is not limited thereto.

In one or more embodiments, the display panel DP may have a planar display surface. In one or more embodiments, the display panel DP may have an at least partially rounded display surface. In one or more embodiments, the display panel DP may be bendable, foldable, and/or rollable. In the aforementioned cases, the display panel DP and/or the substrate SUB may include materials having flexible properties.

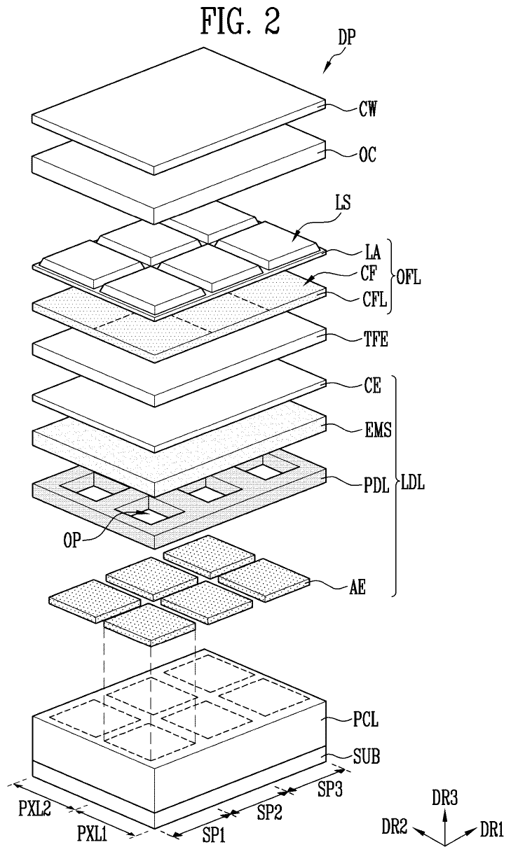

FIG. 2 is a schematic exploded perspective view illustrating a portion of the display panel of FIG. 1. In FIG. 2, for the sake of clear and concise explanation, there is schematically illustrated a portion of the display panel DP corresponding to two pixels PXL1 and PXL2 from among the pixels PXL of FIG. 1. The remaining portions of the display panel DP corresponding to the other pixels may also be configured in substantially the same manner.

Referring to FIG. 2, each of the first and second pixels PXL1 and PXL2 may include first to third sub-pixels SP1, SP2, and SP3, but is not limited thereto. In one or more embodiments, each of the first and second pixels PXL1 and PXL2 may include four sub-pixels, or may include two sub-pixels.

Although in FIG. 2 there is illustrated the case where the first to third sub-pixels SP1, SP2, and SP3 have rectangular shapes and the same size when viewed in a third direction DR3 crossing with the first and second directions DR1 and DR2, but the present disclosure is not limited thereto. In one or more embodiments, the first to third sub-pixels SP1, SP2, and SP3 may be modified to have one or more suitable shapes.

The display panel DP may include the substrate SUB, a pixel circuit layer PCL, a light-emitting-element layer LDL, an encapsulation layer TFE, an optical functional layer OFL, an overcoat layer OC, and a cover window CW.

In one or more embodiments, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, and/or the like. In one or more embodiments, the substrate SUB may include a glass substrate. In one or more embodiments, the substrate SUB may include a polyimide (polyimide) substrate.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may function as at least some of the circuit components, lines, and/or the like. The conductive patterns may include copper, but are not limited thereto.

The circuit elements may include respective sub-pixel circuits of the first to third sub-pixels SP1, SP2, and SP3. The sub-pixel circuit may include transistors and one or more capacitors. Each transistor may include a semiconductor portion including a source area, a drain area, and a channel area, and a gate electrode overlapping the semiconductor portion. In one or more embodiments, in the case where the substrate SUB is formed of a silicon substrate, the semiconductor portion may be included in the substrate SUB, and the gate electrode may be included in the pixel circuit layer PCL as a conductive pattern of the pixel circuit layer PCL. In one or more embodiments, in the case where the substrate SUB is formed of a glass substrate and/or a polyamide (PI) substrate, the semiconductor portion and the gate electrode may be included in the pixel circuit layer PCL. Each capacitor may include electrodes spaced from each other. For example, each capacitor may include electrodes spaced and/or apart from each other on a plane defined in the first and second directions DR1 and DR2. For example, each capacitor may include electrodes spaced and/or apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, and a data line. In one or more embodiments, the lines may further include power voltage lines.

The light emitting element layer LDL may include anode electrodes AE, a pixel defining layer PDL, an emission structure EMS, and a cathode electrode CE.

The anode electrodes AE (or first electrodes) may be disposed on the pixel circuit layer PCL. The anode electrodes AE may contact circuit elements of the pixel circuit layer PCL. The anode electrodes AE may include opaque conductive material capable of reflecting light, but is not limited thereto.

The pixel defining layer PDL may be disposed on the anode electrode AE. The pixel defining layer PDL may include openings OP that expose respective portions of the anode electrodes AE. The openings OP in the pixel defining layer PDL may be understood as respective emission areas corresponding to the first to third sub-pixels SP1, SP2, and SP3.

In one or more embodiments, the pixel defining layer PDL may include inorganic material. In this case, the pixel defining layer PDL may include a plurality of inorganic insulating layers stacked on top of one another. For example, the pixel defining layer PDL may include silicon oxide (SiOₓ) and/or silicon nitride (SiNₓ). In one or more embodiments, the pixel defining layer PDL may include organic material. However, the material of the pixel defining layer PDL is not limited to the foregoing embodiment.

The emission structure EMS may be disposed on the anode electrodes AE (or the first electrode) exposed through the opening OP in the pixel defining layer PDL. The emission structure EMS may include an emission layer configured to generate light, an electron transport layer configured to transport electrons, and a hole transport layer configured to transport holes, but is not limited thereto.

One or more embodiments, the emission structure EMS may fill the openings OP in the pixel defining layer PDL and may be disposed on an overall surface of an upper portion of the pixel defining layer PDL. In other words, the emission structure EMS may extend over the first to third sub-pixels SP1, SP2, and SP3. In this case, at least some of the layers in the emission structure EMS may be interrupted or bent in boundary areas between the first to third sub-pixels SP1, SP2, and SP3. However, the present disclosure is not limited to the aforementioned examples. In one or more embodiments, parts of the emission structure EMS that correspond to the first to third sub-pixels SP1, SP2, and SP3 may be separated from each other and disposed in the corresponding openings OP in the pixel defining layer PDL.

The cathode electrode CE (or a second electrode) may be disposed on the emission structure EMS. The cathode electrode CE may extend over the first to third sub-pixels SP1, SP2, and SP3. The cathode electrode CE may be provided as a common electrode for the first to third sub-pixels SP1, SP2, and SP3.

The cathode electrode CE may be a thin-film metal layer having a thickness allowing light emitted from the emission structure EMS to pass therethrough. The cathode electrode CE may include (e.g., be) a metal material having a relatively small thickness, or a transparent conductive material. In one or more embodiments, the cathode electrode CE may include at least one of one or more suitable transparent conductive materials including indium tin oxide, indium zinc oxide, indium tin zinc oxide, aluminum zinc oxide, gallium zinc oxide, zinc tin oxide, and/or gallium tin oxide. In one or more embodiments, the cathode electrode CE may include at least one of magnesium, silver, and/or a compound thereof. However, the material of the cathode electrode CE is not limited to the foregoing embodiment.

One of the anode electrodes AE, a portion of the emission structure EMS that overlap the one of the anode electrodes AE, and a portion of the cathode electrode CE that overlaps the portion of the emission structure EMS may be understood as constituting one light emitting element. In other words, each of the light emitting elements of the first to third sub-pixels SP1, SP2, and SP3 may include one anode electrode AE (or one first electrode), a portion of the emission structure EMS that overlaps the one anode electrode AE, and a portion of the cathode electrode CE (or the second electrode) that overlaps the portion of the emission structure EMS. In each of the first to third sub-pixels SP1, SP2, and SP3, holes injected from the anode electrode AE and electrons injected from the cathode electrode CE are transported into the emission layer of the emission structure EMS, thus forming excitons. In case that the excitons make a transition from an excited state to a ground state, light may be generated. Depending on the amount of current flowing through the emission layer, the luminance of light may be determined. Depending on the configuration of the emission layer, the wavelength range of light to be generated may be determined.

The encapsulation layer TFE may be disposed on the cathode electrode CE. The encapsulation layer TFE may cover the light emitting element layer LDL and/or the pixel circuit layer PCL. The encapsulation layer TFE may be configured to prevent or reduce oxygen, water, and/or the like from penetrating into the light-emitting-element layer LDL. In one or more embodiments, the encapsulation layer TFE may include a structure formed by alternately stacking one or more inorganic layers and one or more organic layers. For example, the inorganic layer may include silicon nitride, silicon oxide, silicon oxynitride (SiOₓN_{y}), and/or the like. For example, the organic layer may include organic insulating material such as polyacrylate resin, epoxy resin, phenolic resin, polyamide resin, polyimide resin, unsaturated polyester resin, polyphenylene resin, polyphenylene sulfide resin, and/or benzocyclobutene (BCB). However, the materials of the organic layer and the inorganic layer of the encapsulation layer TFE are limited to the aforementioned examples.

The encapsulation layer TFE may further include a thin film, including aluminum oxide (AlOₓ), to enhance the encapsulation efficiency of the encapsulation layer TFE. The thin film including aluminum oxide may be positioned on an upper surface of the encapsulation layer TFE that faces the optical functional layer OFL and/or under a lower surface of the encapsulation layer TFE that faces the light-emitting-element layer LDL.

The thin film including aluminum oxide may be formed through an atomic layer deposition (ALD) method. However, the present disclosure is not limited to the aforementioned example. The encapsulation layer TFE may further include a thin film formed of at least one of one or more suitable materials suitable for enhancing the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter light emitted from the emission structure EMS to selectively output light in a wavelength range or color corresponding to each sub-pixel. The color filter layer CFL may include color filters CF that respectively correspond to the first to third sub-pixels SP1, SP2, and SP3. Each of the color filters CF allows light in a wavelength range corresponding to the corresponding sub-pixel to pass therethrough. For example, the color filter that corresponds to the first sub-pixel SP1 allows light in red to pass therethrough, the color filter that corresponds to the second sub-pixel SP2 allows light in green to pass therethrough, and the color filter that corresponds to the third sub-pixel SP3 allows light in blue to pass therethrough. Depending on the light emitted from the emission structure EMS of each sub-pixel, at least some of the color filters CF may not be provided.

The lens array LA may be disposed on the color filter layer CFL. The lens array LA may include lenses LS that respectively correspond to the first to third sub-pixels SP1, SP2, and SP3. Each of the lenses LS may direct light emitted from the emission structure EMS along an intended path, thus enhancing the light output efficiency. The lens array LA may have a relatively high refractive index. For example, the lens array LA may have a higher refractive index than the overcoat layer OC. In one or more embodiments, the lenses LS may include organic material. For example, the lenses LS may include acrylate material, but are not limited thereto.

In one or more embodiments, compared to the openings OP of the pixel defining layer PDL, at least some of the color filters CF of the color filter layer CFL and at least some of the lenses LS of the lens array LA may be shifted in a direction parallel to the plane defined in the first and second directions DR1 and DR2. For example, in or at a central area of the display area DA, the center of each color filter CF and the center of each lens LS may be aligned or overlapped with the center of the corresponding opening OP of the pixel defining layer PDL. For example, in or at the central area of the display area DA, each opening OP of the pixel defining layer PDL may completely overlap the corresponding color filter CF of the color filter layer CFL and the corresponding lens LS of the lens array LA. In an area adjacent to the non-display area NDA within the display area DA, the center of the color filter CF and the center of the lens LS may be shifted in a planar direction. For example, in or at the area adjacent to the non-display area NDA within the display area DA, each opening OP of the pixel defining layer PDL may partially overlap the corresponding color filter CF of the color filter layer CFL and the corresponding lens LS of the lens array LA. Hence, light emitted from the emission structure EMS in or at the central portion of the display area DA may be efficiently outputted in the normal direction of the display surface. Light emitted from the emission structure EMS around the perimeter of the display area DA may be efficiently outputted in a direction inclined at a certain angle with respect to the normal direction of the display surface.

The overcoat layer OC may be disposed on the lens array LA. The overcoat layer OC may cover the optical functional layer OFL, the encapsulation layer TFE, the emission structure EMS, and/or the pixel circuit layer PCL. The overcoat layer OC may include one or more suitable materials suitable for protecting underlying layers from foreign substances such as dust, water, and/or the like. For example, the overcoat layer OC may include at least one of an inorganic insulating layer and/or an organic insulating layer. For example, the overcoat layer OC may include epoxy, but it is not limited thereto. The overcoat layer OC may have a lower refractive index than the lens array LA.

The cover window CW may be disposed on the overcoat layer OC. The cover window CW may be configured to protect underlying layers. The cover window CW may have a higher refractive index than the overcoat layer OC. The cover window CW may include glass, but it is not limited thereto. In one or more embodiments, the cover window CW may be an encapsulation glass layer configured to protect components disposed thereunder. In one or more embodiments, the cover window CW may not be provided (e.g., may be excluded).

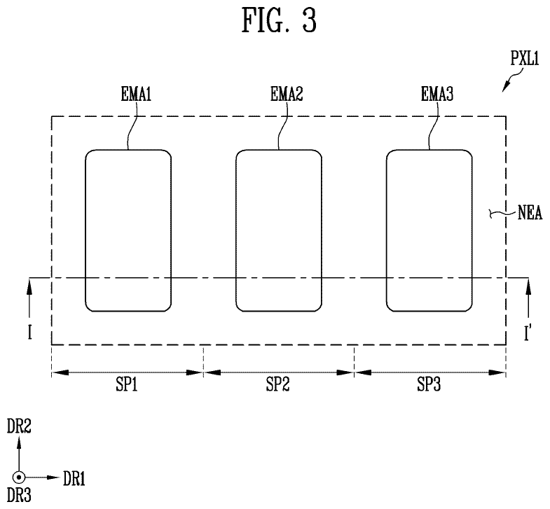

FIG. 3 is a schematic plan view illustrating one or more embodiments of one of the pixels of FIG. 2. In FIG. 3, for the sake of clear and concise explanation, the first pixel PXL1 of the first and second pixels PXL1 and PXL2 of FIG. 2 is schematically depicted. The remaining pixels may have a configuration (or structure) that is substantially identical or similar to the first pixel PXL1.

Referring to FIG. 3, the first pixel PXL1 may include a first sub-pixel SP1, a second sub-pixel SP2, and a third sub-pixel SP3 that are arranged along the first direction DR1.

The first sub-pixel SP1 may include a first emission area EMA1 and a non-

emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

The first emission area EMA1 may be an area where light is emitted from a portion of the emission structure EMS (refer to FIG. 2) that corresponds to the first sub-pixel SP1. The second emission area EMA2 may be an area where light is emitted from a portion of the emission structure EMS that corresponds to the second sub-pixel SP2. The third emission area EMA3 may be an area where light is emitted from a portion of the emission structure EMS that corresponds to the third sub-pixel SP3. As described with reference to FIG. 2, each emission area may be understood as being the opening OP (refer to FIG. 2) of the pixel defining layer PDL (refer to FIG. 2) corresponding to each of the first to third sub-pixels SP1 to SP3.

The first sub-pixel SP1, the second sub-pixel SP2, and the third sub-pixel SP3 may have substantially the same surface area, but are not limited thereto. In one or more embodiments, the second sub-pixel SP2 may have a larger surface area than the first sub-pixel SP1. The third sub-pixel SP3 may have a larger surface area than the second sub-pixel SP2.

Each of the first sub-pixel SP1, the second sub-pixel SP2, and the third sub-pixel SP3 may have a polygonal shape. For example, each of the first sub-pixel SP1, the second sub-pixel SP2, and the third sub-pixel SP3 may have a rectangular shape or a hexagonal shape, but is not limited thereto. In one or more embodiments, each of the first sub-pixel SP1, the second sub-pixel SP2, and the third sub-pixel SP3 may have a circular shape, a semi-elliptical shape, and so on.

The arrangement of the sub-pixels shown in FIG. 3 is an illustrative example, and the present disclosure is not limited thereto. Each pixel may include two or more sub-pixels, and the sub-pixels may be arranged in one or more suitable ways. Each of the sub-pixels may have one or more suitable shapes. Each of the emission areas of the sub-pixels may also have one or more suitable shapes.

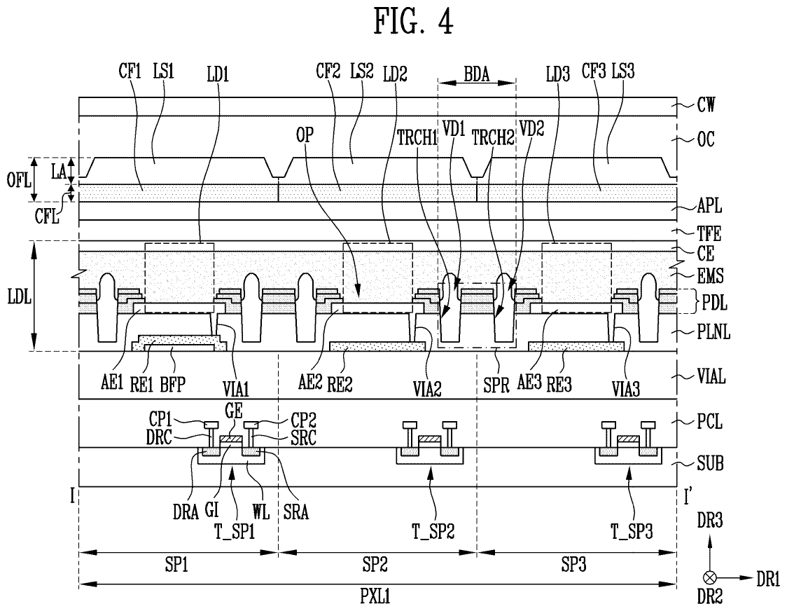

FIG. 4 is a schematic cross-sectional view taken along the line I-I′ of FIG. 3.

Referring to FIGS. 3 and 4, the first pixel PXL1 may include a first sub-pixel SP1, a second sub-pixel SP2, and a third sub-pixel SP3.

Each of the first to third sub-pixels SP1 to SP3 may include the substrate SUB and the pixel circuit layer PCL disposed on the substrate SUB.

The substrate SUB may include a silicon wafer substrate formed through a semiconductor process. For example, the substrate SUB may include silicon, germanium, and/or silicon-germanium.

The pixel circuit layer PCL may be disposed on the substrate SUB. The substrate SUB and the pixel circuit layer PCL may include respective circuit elements of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit of the first sub-pixel SP1. The transistor T_SP2 of the second sub-pixel SP2 may be one of the transistors included in the sub-pixel circuit of the second sub-pixel SP2. The transistor T_SP3 of the third sub-pixel SP3 may be one of the transistors included in the sub-pixel circuit of the third sub-pixel SP3. In FIG. 4, one of the transistors of each sub-pixel is illustrated for the sake of clear and concise explanation, and the remaining circuits are not provided.

The transistor T_SP1 of the first sub-pixel SP1 may include a source area SRA, a drain area DRA, and a gate electrode GE.

The source area SRA and the drain area DRA may be disposed in the substrate SUB. Formed through an ion injection process, a well WL may be disposed in the substrate SUB. The source area SRA and the drain area DRA may be disposed to be spaced and/or apart from each other in the well WL. An area between the source SRA and the drain area DRA in the well WL may be defined as a channel area.

The gate electrode GE may overlap the channel area between the source area SRA and the drain area DRA in the third direction DR3, and may be disposed in the pixel circuit layer PCL. The gate electrode GE may be spaced and/or apart from the well WL or the channel area by an insulating material such as a gate insulating layer GI. The gate electrode GE may include conductive material.

A plurality of layers included in the pixel circuit layer PCL may include insulating layers and conductive patterns disposed between the insulating layers. The conductive patterns may include first and second conductive patterns CP1 and CP2. The first conductive pattern CP1 may be electrically connected to the drain area DRA through a drain connector DRC passing through one or more insulating layers. The second conductive pattern CP2 may be electrically connected to the source area SRA through a source connector SRC passing through one or more insulating layers.

As the gate electrode GE and the first and second conductive patterns CP1 and CP2 are electrically connected to other circuit elements and/or lines, the transistor T_SP1 of the first sub-pixel SP1 may be provided as one of the transistors that constitute the sub-pixel circuit of the first sub-pixel SP1.

Each of the transistor T_SP2 of the second sub-pixel SP2 and the transistor T_SP3 of the third sub-pixel SP3 may have substantially the same configuration as the transistor T_SP1 of the first sub-pixel SP1.

As described above, the substrate SUB and the pixel circuit layer PCL may include respective circuit elements of the first to third sub-pixels SP1 to SP3.

A via layer VIAL may be disposed on the pixel circuit layer PCL. The via layer VIAL may cover the pixel circuit layer PCL, and have an overall even surface. The via layer VIAL may be configured to planarize stepped portions on the pixel circuit layer PCL. The via layer VIAL may include at least one of silicon oxide, silicon nitride, and/or silicon carbon nitride (SiCN), but it is not limited thereto.

The light emitting element layer LDL may be disposed on the via layer VIAL. The light emitting element layer LDL may include first to third reflective electrodes RE1, RE2, and RE3, a planarization layer PLNL, first to third anode electrodes AE1, AE2, and AE3, a pixel defining layer PDL, an emission structure EMS, and a cathode electrode CE.

The first to third reflective electrodes RE1 to RE3 may be respectively disposed in the first to third sub-pixels SP1 to SP3 on the via layer VIAL. For example, the first reflective electrode RE1 may be disposed on the via layer VIAL of the first sub-pixel SP1, the second reflective electrode RE2 may be disposed on the via layer VIAL of the second sub-pixel SP2, and the third reflective electrode RE3 may be disposed on the via layer VIAL of the third sub-pixel SP3. In one or more embodiments, each of the first to third reflective electrodes RE1 to RE3 may contact a circuit element disposed in the pixel circuit layer PCL through a corresponding via hole passing through the via layer VIAL.

The first to third reflective electrodes RE1 to RE3 may function as full mirrors provided to reflect light emitted from the emission structure EMS toward the display surface (or the cover window CW) (e.g., in the third direction DR3). The first to third reflective electrodes RE1 to RE3 may include metallic materials suitable for reflecting light. For example, the first to third reflective electrodes RE1 to RE3 may include at least one of aluminum, silver, magnesium, platinum, palladium, gold, nickel, neodymium, iridium, chromium, and/or titanium, and/or an alloy of two or more materials selected from the aforementioned materials. The material of the first to third reflective electrodes RE1 to RE3 is not limited to the aforementioned embodiment.

In one or more embodiments, a connection electrode may be disposed under each of the first to third reflective electrodes RE1 to RE3. The connection electrode may be provided to enhance electrical connection characteristics between the corresponding reflective electrode and the corresponding circuit element of the pixel circuit layer PCL. The connection electrode may be formed of multiple layers. For example, the multiple layers may include a stacked structure of titanium/titanium nitride/tantalum nitride, but the present disclosure is not limited thereto. In one or more embodiments, between the layers that form the connection electrode, the corresponding reflective electrode may be disposed.

In one or more embodiments, a buffer pattern BFP may be disposed under at least one of the first to third reflective electrodes RE1 to RE3. For example, the buffer pattern BFP may be disposed between the first reflective electrode RE1 and the via layer VIAL. The buffer pattern BFP may include inorganic material such as silicon carbon nitride, but it is not limited thereto. As the buffer pattern BFP is disposed, the height of the corresponding reflective electrode in the third direction DR3 may be adjusted. For example, the buffer pattern BFP may adjust the height of the first reflective electrode RE1 between the first reflective electrode RE1 and the via layer VIAL.

The first to third reflective electrodes RE1 to RE3 may function as full mirrors, and the cathode electrode CE may function as a half mirror. Light emitted from the emission structure EMS may be amplified, at least partially, by reciprocating between the corresponding reflective electrode and the cathode electrode CE. The amplified light may be output through the cathode electrode CE. In this way, the distance between each reflective electrode and the cathode electrode CE may be understood as a resonant distance for the light emitted from the emission layer of the corresponding emission structure EMS.

The first sub-pixel SP1 may have a shorter resonant distance than the other sub-pixels (e.g., the second and third sub-pixels SP2 and SP3) by the buffer pattern BFP. As such, the adjusted resonant distance makes it possible for light in a specific wavelength range (e.g., red color) to be efficiently amplified. Consequently, the first sub-pixel SP1 may effectively and efficiently output light in the corresponding wavelength range.

Although in FIG. 4 there is illustrated the case where the buffer pattern BFP is provided in the first sub-pixel SP1 but is not provided in the second and third sub-pixels SP2 and SP3, the present disclosure is not limited thereto. In one or more embodiments, a buffer pattern BFP may be provided in at least one of the second and third sub-pixels SP2 and SP3 so that the resonant distance of at least one of the second and/or third sub-pixels SP2 and SP3 may be adjusted. For example, in the case where the first sub-pixel SP1 is a red sub-pixel, the second sub-pixel SP2 is a green sub-pixel, and the third sub-pixel SP3 is a blue sub-pixel, a distance between the first reflective electrode RE1 and the cathode electrode CE may be shorter than a distance between the second reflective electrode RE2 and the cathode electrode CE, and a distance between the second reflective electrode RE2 and the cathode electrode CE may be shorter than a distance between the third reflective electrode RE3 and the cathode electrode CE.

The planarization layer PLNL may be provided to planarize stepped portions between the first to third reflective electrodes RE1 to RE3. The planarization layer PLNL may be disposed on the via layer VIAL, and the first to third reflective electrodes RE1 to RE3. The planarization layer PLNL may cover overall surfaces of the first to third reflective electrodes RE1 to RE3 and the via layer VIAL, and have an even surface. In one or more embodiments, the planarization layer PLNL may not be provided.

The first anode electrode AE1, the second anode electrode AE2, and the third anode electrode AE3 may be disposed on the planarization layer PLNL. For example, the first anode electrode AE1 may be disposed on the planarization layer PLNL to overlap the first reflective electrode RE1 in the third direction DR3. The second anode electrode AE2 may be disposed on the planarization layer PLNL to overlap the second reflective electrode RE2 in the third direction DR3. The third anode electrode AE3 may be disposed on the planarization layer PLNL to overlap the third reflective electrode RE3 in the third direction DR3.

The first to third anode electrodes AE1 to AE3 may have a shape similar to the first to third emission areas EMA1 to EMA3 of FIG. 3 when viewed in the third direction DR3. For example, the first anode electrode AE1 may have a shape similar to the first emission area EMA1 when viewed in the third direction DR3. The second anode electrode AE2 may have a shape similar to the second emission area EMA2 when viewed in the third direction DR3. The third anode electrode AE3 may have a shape similar to the third emission area EMA3 when viewed in the third direction DR3. However, the present disclosure is not limited to the aforementioned example.

Each of the first to third anode electrodes AE1 to AE3 may be electrically connected to the corresponding reflective electrode. For example, the first anode electrode AE1 may be electrically connected to the first reflective electrode RE1 through a first via VIA1 passing through the planarization layer PLNL. The second anode electrode AE2 may be electrically connected to the second reflective electrode RE2 through a second via VIA2 passing through the planarization layer PLNL. The third anode electrode AE3 may be electrically connected to the third reflective electrode RE3 through a third via VIA3 passing through the planarization layer PLNL.

In one or more embodiments, the first to third anode electrodes AE1 to AE3 may include at least one of transparent conductive oxide such as indium tin oxide (ITO), indium zinc oxide (IZO), zinc oxide (ZnOₓ), indium gallium zinc oxide (IGZO), and/or indium tin zinc oxide (ITZO). However, the material of the first to third anode electrodes AE1 to AE3 is not limited to the aforementioned example. For example, the first to third anode electrodes AE1 to AE3 may include titanium nitride.

Insulating layers may be further provided to adjust the heights of one or more of the first to third anode electrodes AE1 to AE3. The insulating layers may be disposed between one or more of the first to third anode electrodes AE1 to AE3 and the corresponding reflective electrodes RE1 to RE3. In this case, the planarization layer PLNL and/or the buffer pattern BFP may not be provided.

The pixel defining layer PDL may be disposed on the planarization layer PLNL and portions of the first to third anode electrodes AE1 to AE3. The pixel defining layer PDL may include openings OP that expose respective portions of the first to third anode electrodes AE1 to AE3. The openings OP in the pixel defining layer PDL may define the respective emission areas of the first to third sub-pixels SP1 to SP3. The pixel defining layer PDL may be disposed in the non-emission area NEA (refer to FIG. 3) and define the first emission area EMA1, the second emission area EMA2, and the third emission area EMA3 that are described with reference to FIG. 3.

In one or more embodiments, the pixel defining layer PDL may include a plurality of inorganic insulating layers. Each of the inorganic insulating layers may include at least one of silicon oxide and/or silicon nitride. For example, the pixel defining layer PDL may include first to third inorganic insulating layers that are successively stacked. The first to third inorganic insulating layers may respectively include silicon nitride, silicon oxide, and/or silicon nitride. However, the materials of the pixel defining layer PDL are not limited to the foregoing embodiment.

A separator SPR may be provided in a boundary area between the adjacent sub-pixels. The separator SPR may result in creation of discontinuous portions in the emission structure EMS in the boundary area BDA. For example, the emission structure EMS may be interrupted or bent in the boundary area BDA by the separator SPR.

The separator SPR may be provided in or on the pixel defining layer PDL. The pixel defining layer PDL may include one or more trenches TRCH1 and TRCH2 in the boundary area BDA as the separator SPR. In one or more embodiments, the one or more trenches TRCH1 and TRCH2 may be formed to pass through the pixel defining layer PDL and partially pass through the planarization layer PLNL. In one or more embodiments, the one or more trenches TRCH1 and TRCH2 may be formed to pass through the pixel defining layer PDL and the planarization layer PLNL and partially pass through the via layer VIAL. In one or more embodiments, the one or more trenches TRCH1 and TRCH2 may pass at least partially through the planarization layer PLNL and/or the via layer VIAL, and a portion of the pixel defining layer PDL may be disposed in the one or more trenches TRCH1 and TRCH2. In one or more embodiments, the one or more trenches TRCH1 and TRCH2 may be formed to partially pass through the pixel defining layer PDL.

In FIG. 4, there is illustrated the case where two trenches TRCH1 and TRCH2 are positioned in the boundary area BDA between the sub-pixels, but the present disclosure is not limited thereto. For example, the separator SPR including one trench in the boundary area BDA may be provided in and/or on the pixel defining layer PDL. In some embodiments, the separator SPR including three or more trenches in the boundary area BDA may be provided in and/or on the pixel defining layer PDL.

Due to the first and second trenches TRCH1 and TRCH2, discontinuous portions such as a first void VD1 and a second void VD2 may be formed in the emission structure EMS in the boundary area BDA. Some of the plurality of layers stacked in the emission structure EMS (or the components included in the emission structure EMS) may be interrupted or bent by the first and second voids VD1 and VD2. For example, at least one charge generation layer included in the emission structure EMS may be interrupted by the first and second voids VD1 and VD2. As such, due to the first and second trenches TRCH1 and TRCH2, the emission structure EMS included in the first to third sub-pixels SP1 to SP3 are divided at least partially into parts.

In FIG. 4, there is illustrated the case where the first and second voids VD1 and VD2 are formed in the emission structure EMS in the boundary area BDA, but the present disclosure is limited thereto. For example, a valley having a concave shape may be formed in the emission structure EMS in the boundary area BDA.

Depending on the shapes of the first and second trenches TRCH1 and TRCH2, the shapes and/or the like of the discontinuous portions formed in the emission structure EMS, e.g., the first and second voids VD1 and VD2, may be changed in one or more suitable ways.

In one or more embodiments, the emission structure EMS may be formed through a process such as vacuum deposition, and/or inkjet printing. In this case, the same materials as some components included in the emission structure EMS may be positioned on bottom surfaces adjacent to the via layer VIAL in the first and second trenches TRCH1 and TRCH2.

The separator SPR may be modified in one or more suitable ways to allow the emission structure EMS to have the discontinuous portions in the boundary area BDA. In one or more embodiments, additional inorganic insulating patterns may be provided on the pixel defining layer PDL in the boundary area BDA without the first and second trenches TRCH1 and TRCH2. The uppermost inorganic insulating pattern from among the additionally stacked inorganic insulating patterns may have a width greater than that of the immediately underlying inorganic insulating pattern. For example, in the boundary area BDA, the first to third inorganic insulating patterns may be successively stacked from the pixel defining layer PDL. The uppermost third inorganic insulating pattern may have a width greater than that of the second inorganic insulating pattern. In this case, the pixel defining layer PDL may have a “T”-shaped or “I”-shaped cross-section in the boundary area BDA. Depending on the shape of the pixel defining layer PDL, a plurality of layers included in the emission structure EMS may be at least partially interrupted or bent in the boundary area BDA.

The emission structure EMS may be disposed on the anode electrodes AE (refer to FIG. 2) (or the first electrodes) that are exposed through the opening OP in the pixel defining layer PDL. The emission structure EMS may fill the opening OP of the pixel defining layer PDL, and may be disposed over the overall areas of the first to third sub-pixels SP1 to SP3. As described above, the emission structure EMS may be at least partially interrupted or bent in the boundary area BDA by the separator SPR. Consequently, during the operation of the display panel DP (refer to FIG. 2), current leaking from each of the first to third sub-pixels SP1 to SP3 to the adjacent sub-pixel through the layers included in the emission structure EMS may be reduced. As a result, the first, second, and third light emitting elements LD1, LD2, and LD3 may be operated with a relatively high reliability.

The cathode electrode CE may be disposed on the emission structure EMS. The cathode electrode CE may be provided in common to the first to third sub-pixels SP1 to SP3. The cathode electrode CE may function as a half mirror, partially transmitting and partially reflecting light emitted from the emission structure EMS.

The first anode electrode AE1 (or the first electrode), the portion of the emission structure EMS that overlaps the first anode electrode AE1, and the portion of the cathode electrode CE (or the second electrode) that overlaps the first anode electrode AE1 may form the first light emitting element LD1. The second anode electrode AE2 (or the first electrode), the portion of the emission structure EMS that overlaps the second anode electrode AE2, the portion of the cathode electrode CE (or the second electrode) that overlaps the second anode electrode AE2 may form the second light emitting element LD2. The third anode electrode AE3 (or the first electrode), the portion of the emission structure EMS that overlaps the third anode electrode AE3, the portion of the cathode electrode CE (or the second electrode) that overlaps the third anode electrode AE3 may form the third light emitting element LD3.

The encapsulation layer TFE may be disposed on the cathode electrode CE. The encapsulation layer TFE may prevent or reduce oxygen, water and/or the like from penetrating into the light-emitting-element layer LDL.

The optical functional layer OFL may be disposed on the encapsulation layer TFE. In one or more embodiments, the optical functional layer OFL may be attached to the encapsulation layer TFE through an adhesive layer APL. For example, the optical functional layer OFL may be fabricated through a separate process and attached to the encapsulation layer TFE by the adhesive layer APL. The adhesive layer APL may further perform a function of protecting underlying layers including the encapsulation layer TFE.

The optical functional layer OFL may include the color filter layer CFL and the lens array LA.

The color filter layer CFL may include first to third color filters CF1 to CF3 respectively corresponding to the first to third sub-pixels SP1 to SP3. For example, the color filter layer CFL may include the first color filter CF1 corresponding to the first sub-pixel SP1, the second color filter CF2 corresponding to the second sub-pixel SP2, and the third color filter CF3 corresponding to the third sub-pixel SP3. The first to third color filters CF1 to CF3 may be to transmit light in different wavelength ranges. For example, the first color filter CF1 may be to transmit light in red color, the second color filter CF2 may be to transmit light in green color, and the third color filter CF3 may be to transmit light in blue color. In this case, the first sub-pixel SP1 may be a red sub-pixel, the second sub-pixel SP2 may be a green sub-pixel, and the third sub-pixel SP3 may be a blue sub-pixel.

In one or more embodiments, the first to third color filters CF1 to CF3 may partially overlap each other in the boundary area BDA. In one or more embodiments, the first to third color filters CF1 to CF3 may be spaced and/or apart from each other. A black matrix may be provided between the first to third color filters CF1 to CF3 that are spaced and/or apart from each other.

The lens array LA may be disposed on the color filter layer CFL. The lens array LA may include first to third lenses LS1 to LS3 respectively corresponding to the first to third sub-pixels SP1 to SP3. For example, the lens array LA may include the first lens LS1 corresponding to the first sub-pixel SP1, the second lens LS2 corresponding to the second sub-pixel SP2, and the third lens LS3 corresponding to the third sub-pixel SP3. The first to third lenses LS1 to LS3 may respectively direct light emitted from the first to third light emitting elements LD1 to LD3 in intended paths, thus enhancing the light output efficiency.

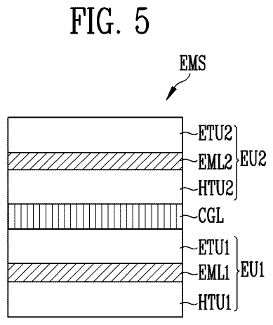

FIG. 5 is a schematic cross-sectional view illustrating one or more embodiments of the emission structure EMS included in one of (e.g., at least one selected from among) the first to third light emitting elements LD1 to LD3 of FIG. 4.

Referring to FIGS. 4 and 5, the emission structure EMS may have a tandem structure in which first and second emission components EU1 and EU2 are stacked. The emission structure EMS may have a substantially identical configuration in each of the first to third light emitting elements LD1 to LD3 of FIG. 4.

Each of the first and second emission components EU1 and EU2 may include at least one emission layer configured to generate light in response to current applied thereto. The first emission component EU1 may include a first emission layer EML1, a first electron transport component ETU1, and a first hole transport component HTU1. The first emission layer EML1 may be disposed between the first electron transport component ETU1 and the first hole transport component HTU1. The second emission component EU2 may include a second emission layer EML2, a second electron transport component ETU2, and a second hole transport component HTU2. The second emission layer EML2 may be disposed between the second electron transport component ETU2 and the second hole transport component HTU2.

Each of the first and second hole transport components HTU1 and HTU2 may include at least one of a hole injection layer and/or a hole transport layer, and may further include a hole buffer layer, an electron blocking layer, and/or the like, as needed. The first and second hole transport components HTU1 and HTU2 may have the same configuration or have different configurations.

Each of the first and second electron transport components ETU1 and ETU2 may include at least one of an electron injection layer and/or an electron transport layer, and may further include an electron buffer layer, a hole blocking layer, and/or the like, as needed. The first and second electron transport components ETU1 and ETU2 may have the same configuration or have different configurations.

An intermediate layer (or connection layer) that may be provided in the form of a charge generation layer CGL may be disposed between the first emission component EU1 and the second emission component EU2, thus connecting the first emission component EU1 and the second emission component EU2 to each other. Hereinafter, the charge generation layer CGL will be referred to as an intermediate layer. In one or more embodiments, the intermediate layer CGL may have a stacked structure including a p-dopant layer and an n-dopant layer. For example, the p-dopant layer may include a p-type or kind dopant such as HAT-CN, TCNQ, or NDP-9, and the n-dopant layer may include alkali metal, alkaline earth metal, lanthanide metal, or a combination thereof. However, the structure (or material) of the intermediate layer CGL is not limited to the aforementioned embodiments. In one or more embodiments, the intermediate layer CGL may include a material with a relatively high charge conductivity (or charge mobility) compared to the first and second emission components EU1 and EU2, thus having conductive properties.

In one or more embodiments, the first emission layer EML1 and the second emission layer EML2 may generate light in different colors. The light emitted from the first emission layer EML1 and the second emission layer EML2 may be mixed to be visible as white light. For example, the first emission layer EML1 may generate light in blue color, and the second emission layer EML2 may include a stacked structure including a first sub-emission layer configured to generate light in red color and a second sub-emission layer configured to generate light in green color. In this case, a functional layer configured to perform functions of transporting holes and/or blocking the transport of electrons may be further disposed between the first and second sub-emission layers.

In one or more embodiments, the first emission layer EML1 and the second emission layer EML2 may generate light in substantially the same color.

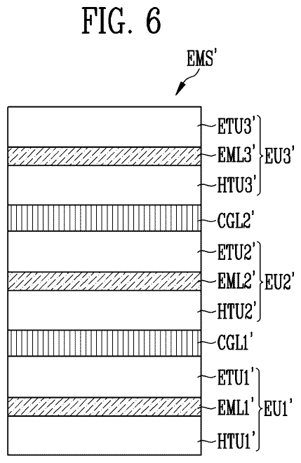

FIG. 6 is a schematic cross-sectional view illustrating an embodiment of the emission structure included in one of the first to third light emitting elements of FIG. 4.

Referring to FIGS. 4 and 6, an emission structure EMS′ may have a tandem structure in which first, second, and third emission components EU1′, EU2′, and EU3′ are stacked. The emission structure EMS′ may have a substantially identical configuration in each of the first to third light emitting elements LD1 to LD3 of FIG. 4.

Each of the first to third emission components EU1′ to EU3′ may include an emission layer configured to generate light in response to current applied thereto. The first emission component EU1′ may include a first emission layer EML1′, a first electron transport component ETU1′, and a first hole transport component HTU1′. The first emission layer EML1′ may be disposed between the first electron transport component ETU1′ and the first hole transport component HTU1′. The second emission component EU2′ may include a second emission layer EML2′, a second electron transport component ETU2′, and a second hole transport component HTU2′. The second emission layer EML2′ may be disposed between the second electron transport component ETU2′ and the second hole transport component HTU2′. The third emission component EU3′ may include a third emission layer EML3′, a third electron transport component ETU3′, and a third hole transport component HTU3′. The third emission layer EML3′ may be disposed between the third electron transport component ETU3′ and the third hole transport component HTU3′.

Each of the first to third hole transport components HTU1′ to HTU3′ may include at least one of a hole injection layer and/or a hole transport layer, and may further include a hole buffer layer, an electron blocking layer, and/or the like, as needed. The first to third hole transport components HTU1′ to HTU3′ may have the same configuration or have different configurations.

Each of the first to third electron transport components ETU1′ to ETU3′ may include at least one of an electron injection layer and an electron transport layer, and may further include an electron buffer layer, a hole blocking layer, and/or the like, as needed. The first to third electron transport components ETU1′ to ETU3′ may have the same configuration or have different configurations.

A first intermediate layer CGL1′ may be disposed between the first emission component EU1′ and the second emission component EU2′. A second intermediate layer CGL2′ may be disposed between the second emission component EU2′ and the third emission component EU3′. In one or more embodiments, the first intermediate layer CGL1′ and the second intermediate layer CGL2′ may include a material with a relatively high charge conductivity (or charge mobility) compared to (that of each of) the first emission component EU1′, the second emission component EU2′, and the third emission component EU3′, thus having conductive properties (e.g., being conductors).

In one or more embodiments, the first to third emission layers EML1′ to EML3′ may generate light in different colors. Light emitted from the first to third emission layers EML1′ to EML3′ may be mixed to be visible as white light. For example, the first emission layer EML1′ may generate light in blue color, the second emission layer EML2′ may generate light in green color, and the third emission layer EML3′ may generate light in red color.

In one or more embodiments, two or more emission layers from among the first to third emission layers EML1′ to EML3′ may generate light in substantially the same color.

Unlike the case described with reference to FIGS. 5 and 6, the emission structure EMS of FIG. 4 may include one emission component in each of the first to third light emitting elements LD1 to LD3. Here, the respective emission components included in the first to third light emitting elements LD1 to LD3 may be configured to emit light in different colors. For example, the emission component of the first light emitting element LD1 may be to emit light in red color, the emission component of the second light emitting element LD2 may be to emit light in green color, and the emission component of the third light emitting element LD3 may be to emit light in blue color. In this case, unlike the case described with reference to FIG. 4, the emission components of the first to third sub-pixels SP1 to SP3 may be separated from each other and disposed in the corresponding openings OP of the pixel defining layer PDL. As described above, in the case where the emission component of the first sub-pixel SP1, the emission component of the second sub-pixel SP2, and the emission component of the third sub-pixel SP3 are separated from each other and disposed in the corresponding openings OP of the pixel defining layer PDL, at least some of the first to third color filters CF1 to CF3 may not be provided.

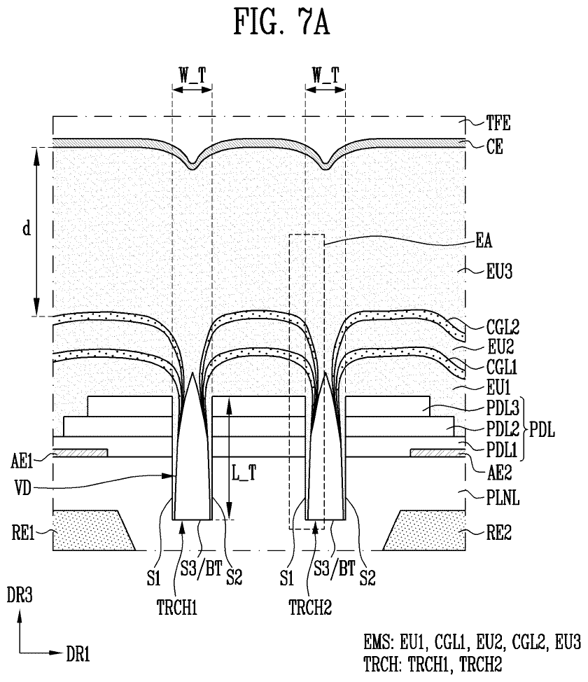

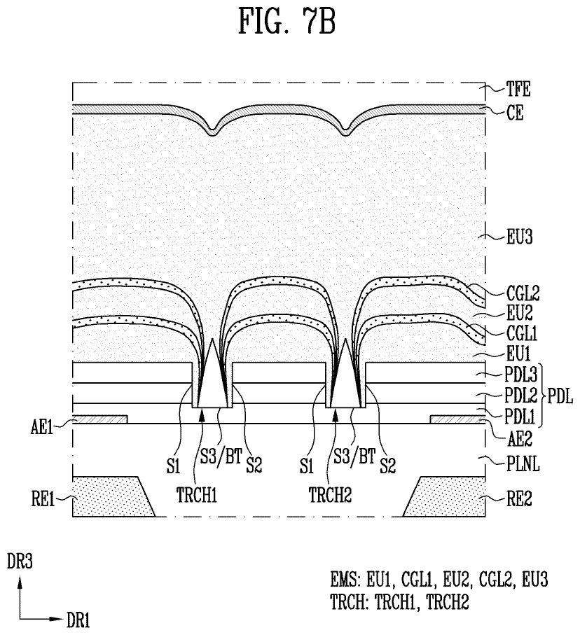

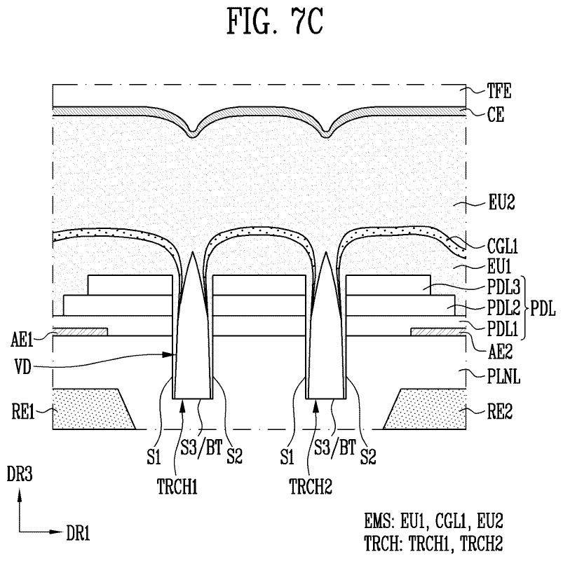

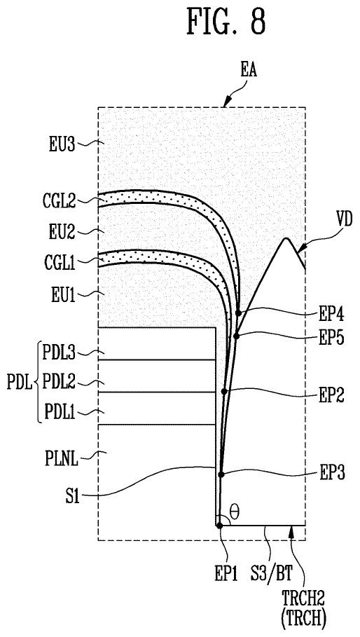

FIGS. 7A to 7C are schematic sectional views each showing an enlargement of a portion of the display device of FIG. 4. FIG. 8 is a schematic view illustrating an enlargement of a portion EA of FIG. 7A.

FIGS. 7A to 7C each illustrate the emission structure EMS and the cathode electrode CE in some areas including the first and second trenches TRCH1 and TRCH2 (e.g., a boundary area between the first sub-pixel SP1 and the second sub-pixel SP2). Furthermore, for the sake of clarity, FIGS. 7A to 7C each further illustrate the planarization layer PLNL, the pixel defining layer PDL, and the encapsulation layer TFE.

The description with reference to FIGS. 7A to 8 will be focused on differences from the above-mentioned embodiments so as to avoid redundant description.

Referring to FIGS. 4 to 8, the pixel defining layer PDL may be disposed on the planarization layer PLNL.

The pixel defining layer PDL may include a first inorganic insulating layer PDL1 (or a first inorganic layer), a second inorganic insulating layer PDL2 (or a second inorganic layer), and a third inorganic insulating layer PDL3 (or a third inorganic layer) that are successively stacked in the third direction DR3, but the configuration of the pixel defining layer PDL is not limited thereto. In one or more embodiments, the pixel defining layer PDL may further include additional inorganic insulating layers in addition to the aforementioned inorganic insulating layers.

The first inorganic insulating layer PDL1 and the third inorganic insulating layer PDL3 may include silicon nitride, and the second inorganic insulating layer PDL2 may include silicon oxide. The material of the first to third inorganic insulating layers PDL1, PDL2, and PDL3 is not limited to the aforementioned embodiment. The pixel defining layer PDL including the first, second, and third inorganic insulating layers PDL1, PDL2, and PDL3 may have a step-shaped cross-section in an area adjacent to the opening OP (refer to FIG. 4), but the present disclosure is not limited thereto. In one or more embodiments, as illustrated FIG. 7B, the pixel defining layer PDL may not have a step-shaped cross-section in the area adjacent to the opening OP.

The trenches TRCH1 and TRCH2 may be positioned between the first sub-pixel SP1 and the second sub-pixel SP2. For example, the first trench TRCH1 and the second trench TRCH2 may be positioned in the boundary area BDA (refer to FIG. 4) (or the non-emission area NEA) between the first sub-pixel SP1 and the second sub-pixel SP2.

As illustrated in FIG. 7A, each of the first and second trenches TRCH1 and TRCH2 may include a penetrated portion passing through at least a portion of the pixel defining layer PDL, and a recessed portion in the planarization layer PLNL, or may be defined (or formed) by the penetrated portion and the recessed portion. The first and second trenches TRCH1 and TRCH2 may be formed by an etching method, e.g., a dry etching method and/or the like, but the present disclosure is not limited thereto. In other words, each of the first and second trenches TRCH1 and TRCH2 may be formed by removing at least portions of the pixel defining layer PDL and the planarization layer PLNL in a direction from an upper surface of the pixel defining layer PDL toward a lower surface of the planarization layer PLNL. In one or more embodiments, as illustrated in FIG. 7B, each of the first and second trenches TRCH1 and TRCH2 may be formed by removing only at least a portion of the pixel defining layer PDL.

Each of the first and second trenches TRCH1 and TRCH2 may be disposed in a shape, enclosing the emission area of the corresponding sub-pixel in the boundary area BDA between the first sub-pixel SP1 and the second sub-pixel SP2, but the present disclosure is not limited thereto.

In one or more embodiments, the pixel defining layer PDL and the planarization layer PLNL may include a first surface S1 and a second surface S2 that face each other in the first direction DR1 with each of the first and second trenches TRCH1 and TRCH2 interposed therebetween. The pixel defining layer PDL and the planarization layer PLNL may include a third surface S3 connecting the first surface S1 and the second surface S2 to each other. The first surface S1 may be a first sidewall of each of the first and second trenches TRCH1 and TRCH2. The second surface S2 may be a second sidewall of each of the first and second trenches TRCH1 and TRCH2. The third surface S3 may be a bottom surface BT of each of the first and second trenches TRCH1 and TRCH2. Hereinafter, for convenience of explanation, the first surface S1 is referred to as a first sidewall of the trench TRCH, the second surface S2 is referred to as a second sidewall of the trench TRCH, and the third surface S3 is referred to as a bottom surface of the trench TRCH.

In one or more embodiments, a width W_T of each of the first and second trenches TRCH1 and TRCH2 may range from approximately 110 nm to approximately 210 nm, but is not limited thereto. The width W_T of each of the first and second trenches TRCH1 and TRCH2 may be about 210 nm or less. A depth L_T of each of the first and second trenches TRCH1 and TRCH2 may range from approximately 2700 Å to approximately 3300 Å, but is not limited thereto. The depth L_T of each of the first and second trenches TRCH1 and TRCH2 may be about 2000 Å or more. In one or more embodiments, a ratio of the width W_T and the depth L_T of each trench TRCH may be 1:3 or more. In one or more embodiments, an angle θ of each trench TRCH may be determined by an inclination of each of the first and second sidewalls S1 and S2 with respect to the bottom surface BT. The angle θ of each trench TRCH may be set within a range from approximately (about) 80° to approximately (about) 90° to enable first and second intermediate layers CGL1 and CGL2 from among the components disposed on the first and second sidewalls S1 and S2 to be interrupted in each trench TRCH.

The depth L_T and the width W_T of each trench TRCH and the thickness of each of the first to third emission component EU1, EU2, and EU3 may be set, taking into account the discontinuity of the first and second intermediate layers CGL1 and CGL2, the connection (and the resonant distance) of the cathode electrode CE, and so on. For example, in the case where the width W_T of each trench TRCH is greater than 210 nm, the cathode electrode CE may be interrupted by stepped differences caused by the components disposed thereunder in the trench TRCH, thus potentially resulting in malfunction of the sub-pixels.

The emission structure EMS may be disposed on the pixel defining layer PDL. The emission structure EMS may include a first emission component EU1, a second emission component EU2, and a third emission component EU3. The emission structure EMS may have substantially the same configuration in each of the first, second, and third emitting elements LD1, LD2, and LD3 described with reference to FIG. 4, but the present disclosure is not limited thereto. In one or more embodiments, the emission structure EMS may be formed by a vacuum deposition method.

The emission structure EMS may further include the first intermediate layer CGL1 and the second intermediate layer CGL2. The first intermediate layer CGL1 (or first charge generation layer) may be disposed between the first emission component EU1 and the second emission component EU2. The second intermediate layer CGL2 (or second charge generation layer) may be disposed between the second emission component EU2 and the third emission component EU3.

In one or more embodiments, each of the first, second, and third emission components EU1, EU2, and EU3 may include an emission layer configured to generate light in response to current applied thereto. The first emission component EU1 may be the same as the first emission component EU1′ described with reference to FIG. 6. The second emission component EU2 may be the same as the second emission component EU2′ described with reference to FIG. 6. The third emission component EU3 may be the same as the third emission component EU3′ described with reference to FIG. 6.

Each of the first, second, and third emission components EU1, EU2, and EU3 may include a hole transport component, an emission layer, an electron transport component, a buffer layer, etc., that include a material with a relatively low charge conductivity (or charge mobility) compared to the first and second intermediate layers CGL1 and CGL2. For example, the first emission component EU1 may include a first hole transport component HTU1′ (refer to FIG. 6), a first emission layer EML1′ (refer to FIG. 6), and a first electron transport component ETU1′ (refer to FIG. 6) that include a material with a relatively low charge conductivity (or charge mobility) compared to the first and second intermediate layers CGL1 and CGL2. The second emission component EU2 may include a second hole transport component HTU2′ (refer to FIG. 6), a second emission layer EML2′ (refer to FIG. 6), and a second electron transport component ETU2′ (refer to FIG. 6) that include a material with a relatively low charge conductivity (or charge mobility) compared to the first and second intermediate layers CGL1 and CGL2. The third emission component EU3 may include a third hole transport component HTU3′ (refer to FIG. 6), a third emission layer EML3′ (refer to FIG. 6), and a third electron transport component ETU3′ (refer to FIG. 6) that include a material with a relatively low charge conductivity (or charge mobility) compared to the first and second intermediate layers CGL1 and CGL2.

In one or more embodiments, the first, second, and third emission components EU1, EU2, and EU3 may include a material (e.g., an insulator) with a relatively high insulation, compared to (e.g., that of each of) the first and second intermediate layers CGL1 and CGL2. In this case, although the first, second, and third emission components EU1, EU2, and EU3 are connected to each other over the trench TRCH, current may not be transmitted to adjacent sub-pixels.

The first emission component EU1 and the second emission component EU2 may include interrupted portions (or open areas) in the first and second trenches TRCH1 and TRCH2. The interrupted portions may be defined as portions in which each of the first and second emission components EU1 and EU2 is disconnected in the first and second trenches TRCH1 and TRCH2 rather than being formed to have a substantially continuous structure. In this case, the first emission EU1 of the first sub-pixel SP1 and the first emission component EU1 of the second sub-pixel SP2 may be separated from each other. The second emission component EU2 of the first sub-pixel SP1 and the second emission component EU2 of the second sub-pixel SP2 may be separated from each other.

In one or more embodiments, at least a portion of the third emission component EU3 of the first sub-pixel SP1 and at least a portion of the third emission component EU3 of the second sub-pixel SP2 may be interrupted in the first and second trenches TRCH1 and TRCH2. In more detail, lower surfaces of the third emission components EU3 of the adjacent sub-pixels (e.g., certain surfaces of the third emission components EU3 that contact the second intermediate layer CGL2) may be interrupted in the first and second trenches TRCH1 and TRCH2. Upper surfaces of the third emission components EU3 (e.g., certain surfaces of the third emission components EU3 that contact the cathode electrode CE) and face away from the lower surfaces may be connected to each other. Hence, the third emission component EU3 may not be interrupted in the first and second trenches TRCH1 and TRCH2. In this case, the third emission component EU3 of the first sub-pixel SP1 and the third emission component EU3 of the second sub-pixel SP2 may be connected to each other.

Each of the first intermediate layer CGL1 and the second intermediate layer CGL2 may generate charges. The first intermediate layer CGL1 may connect the first emission component EU1 and the second emission component EU2. The second intermediate layer CGL2 may connect the second emission component EU2 and the third emission component EU3. In one or more embodiments, the first and second intermediate layers CGL1 and CGL2 may include a material with a relatively high charge conductivity (or charge mobility) compared to the first, second, and third emission components EU1, EU2, and EU3, thus having conductive properties.

Each of the first and second intermediate layers CGL1 and CGL2 may include interrupted portions (or an open areas) over (or in) the first and second trenches TRCH1 and TRCH2 in a similar manner to that of the first and second emission components EU1 and EU2. The interrupted portions may be defined as portions in which each of the first and second intermediate layers CGL1 and CGL2 is disconnected in the first and second trenches TRCH1 and TRCH2 rather than being formed to have a substantially continuous structure. In other words, each of the first and second intermediate layers CGL1 and CGL2 may be interrupted over each of the first and second trenches TRCH1 and TRCH2. In this case, leakage of current from one sub-pixel to an adjacent sub-pixel through the first and second intermediate layers CGL1 and CGL2 may be reduced or prevented or reduced, whereby the sub-pixels may be operated with high reliability. Furthermore, in the case where each of the first and second intermediate layers CGL1 and CGL2 is interrupted over each of the first and second trenches TRCH1 and TRCH2, color mixture between adjacent sub-pixels may be reduced or prevented, whereby each sub-pixel may be to emit light in intended color.

In one or more embodiments, the emission structure EMS may include the first emission component EU1, the first intermediate layer CGL1, the second emission component EU2, the second intermediate layer CGL2, and the third emission component EU3 that are successively stacked in the third direction DR3. The first emission component EU1 may be disposed on the corresponding anode electrode AE (refer to FIG. 2) (or the first electrode) and the pixel defining layer PDL. The first intermediate layer CGL1 may be disposed on the first emission component EU1. The second emission component EU2 may be disposed on the first intermediate layer CGL1. The second intermediate layer CGL2 may be disposed on the second emission component EU2. The third emission component EU3 may be disposed on the second intermediate layer CGL2. The cathode electrode CE (or the second electrode) may be disposed on the third emission component EU3.

The first intermediate layer CGL1 may be disposed between the first emission component EU1 and the second emission component EU2, and may be covered with the second emission component EU2. The second intermediate layer CGL2 may be disposed between the second emission component EU2 and the third emission component EU3, and covered with the third emission component EU3. In a cross-sectional view, the first intermediate layer CGL1 and the second intermediate layer CGL2 may face each other with the second emission component EU2 interposed therebetween.

The first emission component EU1 may be formed on the anode electrode AE (or the first electrode) and the pixel defining layer PDL, and may also be formed on the first and second sidewalls S1 and S2 of each of the first and second trenches TRCH1 and TRCH2. Here, on the first and second sidewalls S1 and S2, an end EP1 (hereinafter, referred to as “first end”) of the first emission component EU1 may be positioned adjacent to the bottom surface BT of the trench TRCH and contact the bottom surface BT. In one or more embodiments, the first emission component EU1 may be formed on or not formed on the bottom surface BT of each trench TRCH. The position of the first end EP1 of the first emission component EU1 on the first and second sidewalls S1 and S2 of each trench TRCH may be determined by adjusting an incident angle (or an injection angle) of base material (or deposition material) of the first emission component EU1 during a process of forming the first emission component EU1.

The first intermediate layer CGL1 may be formed on the first emission component EU1, and may also be formed on the first emission component EU1 even on the first and second sidewalls S1 and S2 of each trench TRCH. An end EP2 (hereinafter, referred to as “second end”) of the first intermediate layer CGL1 may be positioned more distant from the bottom surface BT of the trench TRCH than is the first end EP1 of the first emission component EU1. The position of the second end EP2 of the first intermediate layer CGL1 on the first and second sidewalls S1 and S2 of each trench TRCH may be determined by adjusting an incident angle (or an injection angle) of base material (or deposition material) of the first intermediate layer CGL1 during a process of forming the first intermediate layer CGL1. Here, the incident angle of the base material of the first intermediate layer CGL1 may be different from the incident angle of the base material of the first emission component EU1. For example, the incident angle of the base material of the first intermediate layer CGL1 may be set to be less than the incident angle of the base material of the first emission component EU1.

The second emission component EU2 may be formed on the first intermediate layer CGL1, and may also be formed on the first intermediate layer CGL1 even on the first and second sidewalls S1 and S2 of each trench TRCH. An end EP3 (hereinafter, referred to as “third end”) of the second emission component EU2 may be positioned closer to the bottom surface BT of the trench TRCH than is the second end EP2 of the first intermediate layer CGL1. In this case, as illustrated in FIG. 8, in the trench TRCH, the second emission component EU2 may be disposed comparatively deeper than the first intermediate layer CGL1. Hence, the first intermediate layer CGL1 may be covered with the second emission component EU2 in the trench TRCH. In other words, the entirety of the first intermediate layer CGL1, including the second end EP2 thereof, may be completely covered with the second emission component EU2. The position of the third end EP3 of the second emission component EU2 on the first and second sidewalls S1 and S2 of each trench TRCH may be determined by adjusting an incident angle (or an injection angle) of base material (or deposition material) of the second emission component EU2 during a process of forming the second emission component EU2. Here, the incident angle of the base material of the second emission component EU2 may be different from the incident angle of the base material of the first intermediate layer CGL1. For example, the incident angle of the base material of the second emission component EU2 may be set to be greater than the incident angle of the base material of the first intermediate layer CGL1. The incident angle of the base material of the second emission component EU2 may be the same as the incident angle of the base material of the first emission component EU1, but the present disclosure is not limited thereto.

The second intermediate layer CGL2 may be formed on the second emission component EU2, and may also be formed on the second emission component EU2 even on the first and second sidewalls S1 and S2 of each trench TRCH. An end EP4 (hereinafter, referred to as “fourth end”) of the second intermediate layer CGL2 may be positioned more distant from the bottom surface BT of the trench TRCH than is the third end EP3 of the second emission component EU2. In this case, as illustrated in FIG. 8, in the trench TRCH, the second intermediate layer CGL2 may be disposed comparatively thinner than the second emission component EU2 so that a portion of the second intermediate layer CGL2 can be exposed to the outside. The position of the fourth end EP4 of the second intermediate layer CGL2 on the first and second sidewalls S1 and S2 of each trench TRCH may be determined by adjusting an incident angle (or an injection angle) of base material (or deposition material) of the second intermediate layer CGL2 during a process of forming the second intermediate layer CGL2. Here, the incident angle of the base material of the second intermediate layer CGL2 may be different from the incident angle of the base material of the second emission component EU2. For example, the incident angle of the base material of the second intermediate layer CGL2 may be set to be less than the incident angle of the base material of the second emission component EU2. The injection angle of the base material of the second intermediate layer CGL2 may be the same as the injection angle of the base material of the first intermediate layer CGL1, but the present disclosure is not limited thereto.

The third emission component EU3 may be formed on the second intermediate layer CGL2, and may also be formed on the second intermediate layer CGL2 even on the first and second sidewalls S1 and S2 of each trench TRCH. An end EP5 (hereinafter, referred to as “fifth end”) of the third emission component EU3 may be positioned closer to the bottom surface BT of the trench TRCH than is the fourth end EP4 of the second intermediate layer CGL2. In this case, as illustrated in FIG. 8, in the trench TRCH, the third emission component EU3 may be disposed comparatively deeper than the second intermediate layer CGL2. Hence, the second intermediate layer CGL2 may be covered with the third emission component EU3 in the trench TRCH. In other words, the entirety of the second intermediate layer CGL2, including the fourth end EP4 thereof, may be completely covered with the third emission component EU3. The third emission component EU3 may be disposed on a portion of the second emission component EU2 that is exposed to the outside. The position of the fifth end EP5 of the third emission component EU3 on the first and second sidewalls S1 and S2 of each trench TRCH may be determined by adjusting an incident angle (or an injection angle) of base material (or deposition material) of the third emission component EU3 during a process of forming the third emission component EU3. Here, the incident angle of the base material of the third emission component EU3 may be different from the incident angle of the base material of each of the first and second intermediate layers CGL1 and CGL2. For example, the incident angle of the base material of the third emission component EU3 may be set to be greater than the incident angle of the base material of each of the first and second intermediate layers CGL1 and CGL2. The incident angle of the base material of the third emission component EU3 may be the same as the incident angle of the base material of the first emission component EU1 and/or the base material of the second emission component EU2, but the present disclosure is not limited thereto.

The cathode electrode CE may be disposed on the third emission component EU3. The cathode electrode CE (or the second electrode) may be formed of a metal including a conductive material. In one or more embodiments, a thickness d of the third emission component EU3 may be greater than that of each of the first and second emission components EU1 and EU2. The thickness d of the third emission component EU3 may be a distance between the second intermediate layer CGL2 and the cathode electrode CE. In other words, the thickness d of the third emission component EU3 corresponding to the distance between the second intermediate layer CGL2 and the cathode electrode CE may be greater than the distance between the first intermediate layer CGL1 and the second intermediate layer CGL2 (or the thickness of the second emission component EU2). The reason for the aforementioned structure is to prevent or reduce occurrence of defects due to a short-circuit between the cathode electrode CE and the second intermediate layer CGL2 including a material with a high charge conductivity (or charge mobility) to have conductive properties, and to prevent or reduce discontinuities of the cathode electrode CE due to the stepped portions of the underlying components (e.g., the second intermediate layer CGL2, the second emission component EU2, the first intermediate layer CGL1, and the first emission component EU1). In other words, the third emission component EU3 having a relatively large thickness d may ensure a greater distance between the cathode CE and the second intermediate layer CGL2, thus preventing or reducing short-circuit defects between the cathode electrode CE and the second intermediate layer CGL2. Furthermore, due to the third emission component EU3, the step differences of the underlying components may be mitigated so that step coverage of the cathode electrode CE disposed on the third emission component EU3 can be enhanced, thus preventing or reducing defects in which the cathode electrode CE is interrupted in the trench TRCH.

In one or more embodiments, based on the third direction DR3, the thickness of the first and second emission components EU1 and EU2 may be less than a thickness L_T of each of the first and second trenches TRCH1 and TRCH2. The thickness d of the third emission component EU3 may be greater than the thickness L_T of each of the first and second trenches TRCH1 and TRCH2.

Voids VD may be respective formed in the first and second trenches TRCH1 and TRCH2. The voids VD may be the same as the first and second voids VD1 and VD2 described with reference to FIG. 4. The void VD may be enclosed by the first emission component EU1, the second emission component EU2, and the third emission component EU3 in each trench TRCH.

According to the aforementioned embodiment, the first intermediate layer CGL1 (or the first charge generation layer) including a material with a relatively high charge conductivity (or charge mobility) to have conductive properties selected from among the layers constituting the emission structure EMS may be interrupted over each trench TRCH, and may be completely covered with the second emission component EU2 up to the end thereof (or the second end EP2) in the corresponding trench TRCH. Furthermore, the second intermediate layer CGL2 (or the second charge generation layer) including a material with a relatively high charge conductivity (or charge mobility) to have conductive properties may be interrupted over each trench TRCH, and may be completely covered with the third emission component EU3 up to the end thereof (or the fourth end EP4) in the corresponding trench TRCH. Hence, short-circuit defects between the first intermediate layer CGL1 and the second intermediate layer CGL2 that have conductive properties may be reduced or prevented, whereby the reliability of each sub-pixel may be further enhanced.

In accordance with the aforementioned embodiment, the first intermediate layer CGL1, the second intermediate layer CGL2, and the cathode electrode CE (or the second electrode) may be electrically insulated from each other.

In the aforementioned embodiments, the emission structure EMS has been described as having a tandem structure including the first emission component EU1, the second emission component EU2, and the third emission component EU3 that are stacked on top of one another, but the structure thereof is not limited thereto. In one or more embodiments, the emission structure EMS may have a tandem structure including a first emission component EU1 and a second emission component EU2 that are stacked on top of one another, as shown in FIG. 7C. In this case, the emission structure EMS may include a first intermediate layer CGL1 disposed between the first emission component EU1 and the second emission component EU2, in a similar manner to that of the emission structure EMS described with reference to FIG. 5. The first intermediate layer CGL1 may be the same as the intermediate layer CGL of FIG. 5.

Hereinafter, the emission structure EMS including the first and second emission components EU1 and EU2 and the first intermediate layer CGL1 will be described with reference to FIG. 7C.

Each of the first and second emission components EU1 and EU2 may include an emission layer configured to generate light in response to current applied thereto. The first emission component EU1 may be the same as the first emission component EU1 described with reference to FIG. 5. The second emission component EU2 may be the same as the second emission component EU2 described with reference to FIG. 5. Each of the first and second emission components EU1 and EU2 may include a hole transport component, an emission layer, an electron transport component, and a buffer layer that include a material with a relatively low charge conductivity compared to the first intermediate layer CGL1.

The first emission component EU1 may include an interrupted portion in each of the first and second trenches TRCH1 and TRCH2. In this case, the first emission component EU1 of the first sub-pixel SP1 may be separated from the first emission component EU1 of the second sub-pixel SP2.

At least a portion of the second emission component EU2 of the first sub-pixel SP1 and at least a portion of the second emission component EU2 of the second sub-pixel SP2 may be interrupted in the first and second trenches TRCH1 and TRCH2. In detail, lower surfaces of the second emission components EU2 of the adjacent sub-pixels (e.g., certain surfaces of the second emission components EU2 that contact the first intermediate layer CGL1) may be interrupted in the first and second trenches TRCH1 and TRCH2. Upper surfaces of the second emission components EU2 (e.g., certain surfaces of the second emission components EU2 that contact the cathode electrode CE) that face away from the lower surfaces may be connected to each other. Hence, the second emission component EU2 may not be interrupted in the first and second trenches TRCH1 and TRCH2. In this case, the second emission component EU2 of the first sub-pixel SP1 and the second emission component EU2 of the second sub-pixel SP2 may be connected to each other.

The first intermediate layer CGL1 may generate charges. The first intermediate layer CGL1 may be the same as the intermediate layer CGL described with reference to FIG. 5. The first intermediate layer CGL1 may connect the first emission component EU1 and the second emission component EU2. The first intermediate layer CGL1 may include a material with a relatively high charge conductivity, thus having conductive properties. The first intermediate layer CGL1 may include interrupted portions (or open areas) over (or in) the first and second trenches TRCH1 and TRCH2, in a similar manner to that of the first emission component EU1. The first intermediate layer CGL1 may be interrupted over each of the first and second trenches TRCH1 and TRCH2. In this case, leakage of current from one sub-pixel to an adjacent sub-pixel through the first intermediate layer CGL1 may be reduced or prevented, whereby the sub-pixels may be operated with high reliability. Furthermore, in the case where the first intermediate layer CGL1 is interrupted over each of the first and second trenches TRCH1 and TRCH2, color mixture between the adjacent sub-pixels may be prevented or protected from occurring.

The first intermediate layer CGL1 may be formed on the first emission component EU1, and may also be formed on the first emission component EU1 even on the first and second sidewalls S1 and S2 of each trench TRCH. In each trench TRCH, the end of the first intermediate layer CGL1 may be positioned more distant from the bottom surface BT of the trench TRCH than is the first emission component EU1.

The second emission component EU2 may be formed on the first intermediate layer CGL1, and may also be formed on the first intermediate layer CGL1 even on the first and second sidewalls S1 and S2 of each trench TRCH. In each trench TRCH, an end of the second emission component EU2 may be positioned closer to the bottom surface BT of the trench TRCH than is the end of the first intermediate layer CGL1. In this case, on the trench TRCH (or in the trench TRCH), the second emission component EU2 may be disposed relatively deeper than the first intermediate layer CGL1. Hence, the first intermediate layer CGL1 may be covered with the second emission component EU2 in the trench TRCH. In other words, the entirety of the first intermediate layer CGL1, including the end thereof, may be completely covered with the second emission component EU2. The second emission component EU2 may be disposed on a portion of the first emission component EU1 that is exposed to the outside.

The cathode electrode CE may be disposed on the second emission component EU2. The cathode electrode CE (or the second electrode) may be formed of a metal including a conductive material.

A void VD may be formed in each of the first and second trenches TRCH1 and TRCH2. The void VD may be enclosed by the first emission component EU1 and the second emission component EU2 in each trench TRCH.

According to the aforementioned embodiment, the first intermediate layer CGL1 including a material with a relatively high charge conductivity (or charge mobility) to have conductive properties selected from among the layers constituting the emission structure EMS may be interrupted over each trench TRCH, and may be completely covered, up to the end thereof, with the second emission component EU2 including a material with a relatively low charge conductivity in the corresponding trench TRCH. In this case, the first intermediate layer CGL1 and the cathode electrode CE (or the second electrode) may be electrically insulated from each other. Hence, short-circuit defects between the first intermediate layer CGL1 and the cathode electrode CE may be reduced or prevented, whereby the reliability of each sub-pixel may be further enhanced.

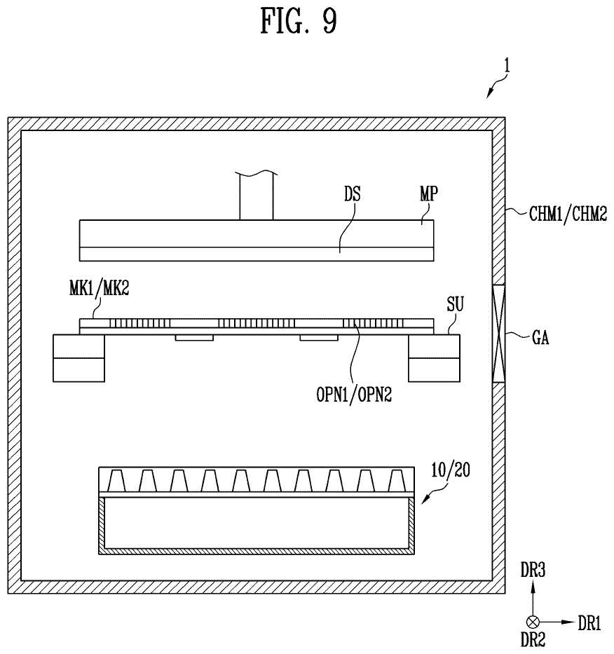

Hereinafter, a method of forming the emission structure EMS on the first and second sidewalls S1 and S2 of the trench TRCH utilizing an apparatus 1 (refer to FIG. 9) for fabricating the display device (e.g., the display device DD of FIG. 1) will be described with reference to FIGS. 9 to 12.

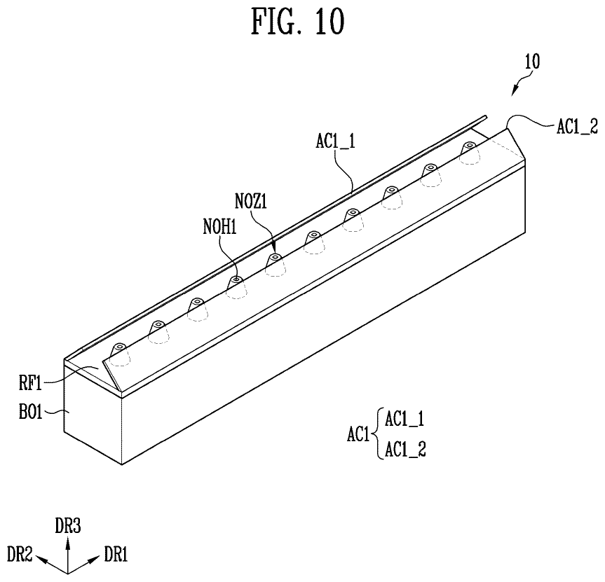

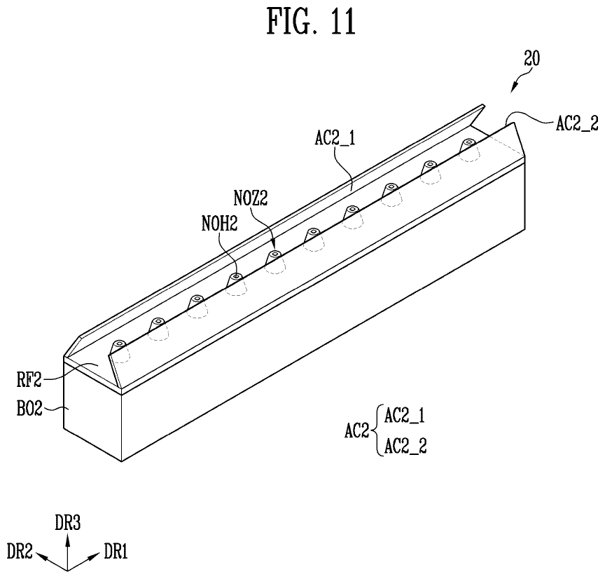

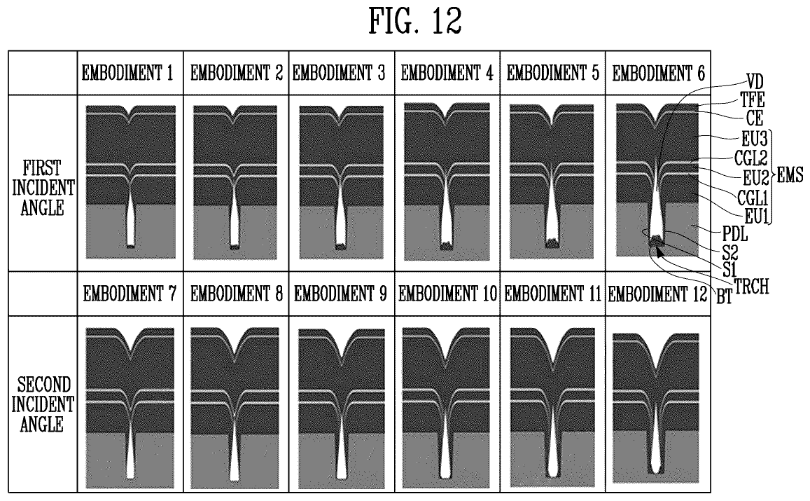

FIG. 9 is a schematic view illustrating one or more embodiments of the apparatus 1 for fabricating the display device. FIG. 10 is a schematic view illustrating a first deposition source 10 of FIG. 9. FIG. 11 is a schematic view illustrating a second deposition source 20 of FIG. 9. FIG. 12 illustrates simulation results of deposition appearance based on incident angles of the components of the emission structure EMS formed on the trench TRCH. In FIG. 9, for convenience of explanation, first deposition chamber CHM1 and second deposition chamber CHM2 are illustrated as having the same structure.

Referring to FIGS. FIGS. 7A to 12, the apparatus 1 for fabricating the display device may be a deposition apparatus for forming the emission structure EMS. Hereinafter, the apparatus 1 for fabricating the display device will be referred to as a deposition apparatus.

The apparatus (e.g., depositor) 1 may include the first deposition chamber CHM1 and the second deposition chamber CHM2 that are separated from each other.

The first deposition chamber CHM1 may provide sealed space for depositing (or forming), on a target substrate DS, each of the first intermediate layer CGL1 and the second intermediate layer CGL2, which include a material with a relatively high charge conductivity to have conductive properties selected from among the components of the emission structure EMS. In one or more embodiment, the first deposition chamber CHM1 may provide a sealed space for depositing (or forming) the cathode electrode CE (or the second electrode) including conductive material on the target substrate DS. The second deposition chamber CHM2 may provide a sealed space for depositing (for forming), on the target substrate DS, each of the first, second, and third emission components EU1, EU2, and EU3 including a material with a relatively low charge conductivity (or low charge mobility) compared to the first and second intermediate layers CGL1 and CGL2 selected from among the components of the emission structure EMS. The interior of each of the first deposition chamber CHM1 and the second deposition chamber CHM2 may be maintained in a reduced-pressure atmosphere.

A movable plate MP, a first mask assembly MK1, and a first deposition source 10 may be disposed in the internal space of the first deposition chamber CHM1. A movable plate MP, a second mask assembly MK2, and a second deposition source 20 may be disposed in the internal space of the second deposition chamber CHM2. Each of the first and second deposition chambers CHM1 and CHM2 may include one or more gates GA. For example, the target substrate DS may move into and out of the corresponding chamber through the gate GA. For example, when deposition of the material of the first intermediate layer CGL1 on the target substrate DS in the first deposition chamber CHM1 is completed, the target substrate DS may move into the second deposition chamber CHM2 through the gate GA of the first deposition chamber CHM1. Furthermore, when deposition of the material of the second emission component EU2 on the target substrate DS in the second deposition chamber CHM2 is completed, the target substrate DS may move into the first deposition chamber CHM1 through the gate GA of the second deposition chamber CHM2.

The movable plate MP may move in the first and second deposition chambers CHM1 and CHM2.

The first mask assembly MK1 may be disposed between the target substrate DS and the first deposition source 10, and may overlap the target substrate DS. The first mask assembly MK1 may be supported by a support component SU. A plurality of first openings OPN1 may be defined in the first mask assembly MK1. Deposition materials sprayed in the first deposition chamber CHM1 may be deposited on the target substrate DS through the first openings OPN1.

The second mask assembly MK2 may be disposed between the target substrate DS and the second deposition source 20, and may overlap the target substrate DS. The second mask assembly MK2 may be supported by a support component SU. A plurality of second openings OPN2 may be defined in the second mask assembly MK2. Deposition materials sprayed in the second deposition chamber CHM2 may be deposited on the target substrate DS through the second openings OPN2.

The first deposition source 10 may be disposed under the first mask assembly MK1 and receive a deposition material therein. The first deposition source 10 may vaporize or sublimate the deposition material received therein and spray the vaporized or sublimated the deposition material onto the target substrate DS. Here, the first deposition source 10 may separately receive a deposition material corresponding to the first intermediate layer CGL1, a deposition material corresponding to the second intermediate layer CGL2, and a deposition material corresponding to the cathode electrode CE.

The first deposition source 10 may include a first main body BO1 and a first angle-limit component AC1. The first main body BO1 may include a crucible for receiving a deposition material, and first nozzles NOZ1 configured to spray the deposition material onto the target substrate DS. A first nozzle hole NOH1 may be defined in each of the first nozzles NOZ1. The first deposition source 10 may include a first reflector RF1 to reduce or prevent or reduce heat from leaking upward from the first main body BO1.

The first angle-limit component AC1 may limit a deposition area of the deposition material that is sprayed toward the target substrate DS through the first nozzles NOZ1. A discharge angle at which the deposition material is discharged from the first main body BO1 may be limited to a certain angle or less by the first angle-limit component AC1. As a result, in the apparatus 1, an incident angle of the deposition material onto the target substrate DS during a process of performing deposition may be limited to a certain angle or less, and patterning accuracy in epitaxial growth through the first mask assembly MK1 may be enhanced. The first angle-limit component AC1 may include a 1-1-th angle-limit component AC1_1 and a 1-2-th angle-limit component AC1_2 that face each other with the first nozzles NOZ1 interposed therebetween. The incident angle of the deposition material (e.g., the deposition material corresponding to the first intermediate layer CGL1 and the deposition material corresponding to the second intermediate layer CGL2) to be sprayed onto the target substrate DS may be controlled or selected by adjusting inclination angles of the 1-1-th angle-limit component AC1_1 and the 1_2-th angle-limit component AC1_2.

The second deposition source 20 may be disposed under the second mask assembly MK2 and receive a deposition material therein. The second deposition source 20 may vaporize or sublimate the deposition material received therein and spray the vaporized or sublimated the deposition material onto the target substrate DS. Here, the second deposition source 20 may separately receive a deposition material corresponding to the first emission component EU1, a deposition material corresponding to the second emission component EU2, and a deposition material corresponding to the third emission component EU3.

The second deposition source 20 may include a second main body BO2 and a second angle-limit component AC2. The second main body BO2 may include a crucible for receiving a deposition material, and second nozzles NOZ2 configured to spray the deposition material onto the target substrate DS. A second nozzle hole NOH2 may be defined in each of the second nozzles NOZ2. The second deposition source 20 may include a second reflector RF2 to reduce or prevent heat from leaking upward from the second main body BO2.

The second angle-limit component AC2 may limit a deposition area of the deposition material that is sprayed toward the target substrate DS through the second nozzles NOZ2. A discharge angle at which the deposition material is discharged from the second main body BO2 may be limited to a certain angle or less by the second angle-limit component AC2. As a result, in the apparatus 1, an incident angle of the deposition material onto the target substrate DS during a process of performing deposition may be limited to a certain angle or less, and patterning accuracy in epitaxial growth through the second mask assembly MK2 may be enhanced. The second angle-limit component AC2 may include a 2-1-th angle-limit component AC2_1 and a 2-2-th angle-limit component AC2_2 that face each other with the second nozzles NOZ2 interposed therebetween. The incident angle of the deposition material to be sprayed onto the target substrate DS may be controlled or selected by adjusting inclination angles of the 2-1-th angle-limit component AC2_1 and the 2_2-th angle-limit component AC2_2.

In one or more embodiments, the inclination angle of the first angle-limit component AC1 and the inclination angle of the second angle-light component AC2 may be different from each other. For example, the inclination angle of the second angle-light component AC2 may be greater than the inclination angle of the first angle-limit component AC1, but it is not limited thereto. The inclination angle of the first angle-limit component AC1 and the inclination angle of the second angle-light component AC2 may be determined depending on the incident angle of the deposition material to be sprayed onto the corresponding target substrate DS.

Hereinafter, the extent of epitaxial growth of the emission structure EMS formed in the trench TRCH for each incident angle will be described with reference to FIG. 12.

Referring to FIG. 12, a first incident angle and a second incident angle may be determined within a range from approximately 40° to approximately 85°. For example, the first incident angle may range from approximately 50° to approximately 60°, and the second incident angle may range from approximately 70° to approximately 75°. The second incident angle may be a high incident angle compared to the first incident angle. The first incident angle may be a low incident angle compared to the second incident angle.

Furthermore, in FIG. 12, embodiment 1 to embodiment 6 are embodiments involving adjusting the inclination angles of the first and second angle-limit components AC1 and AC2 such that the components included in the emission structure EMS (e.g., the first emission component EU1, the first intermediate layer CGL1, the second emission component EU2, the second intermediate layer CGL2, and the third emission component EU3) are incident on the pixel defining layer PDL at the first incident angle (or a low incident angle) during a process of forming the emission structure EMS on the pixel defining layer PDL (or the target substrate DS). Embodiment 7 to embodiment 12 are embodiments involving adjusting the inclination angles of the first and second angle-limit components AC1 and AC2 such that the components included in the emission structure EMS (e.g., the first emission component EU1, the first intermediate layer CGL1, the second emission component EU2, the second intermediate layer CGL2, and the third emission component EU3) are incident on the pixel defining layer PDL at the second incident angle (or a high incident angle) during a process of forming the emission structure EMS on the pixel defining layer PDL (or the target substrate DS).

In embodiment 1 and embodiment 7, the width of the trench TRCH may be approximately 110 nm. In embodiment 2 and embodiment 8, the width of the trench TRCH may be approximately 130 nm. In embodiment 3 and embodiment 9, the width of the trench TRCH may be approximately 150 nm. In embodiment 4 and embodiment 10, the width of the trench TRCH may be approximately 170 nm. In embodiment 5 and embodiment 11, the width of the trench TRCH may be approximately 190 nm. In embodiment 6 and embodiment 12, the width of the trench TRCH may be approximately 210 nm.

In embodiment 1 to embodiment 12, the first emission component EU1, the first intermediate layer CGL1, the second emission component EU2, and the second intermediate layer CGL2 may be interrupted and formed discontinuously over the trench TRCH, and the third emission component EU3 may be formed continuously without interruption. Furthermore, in embodiment 1 to embodiment 12, a portion of the lower surface of the third emission component EU3 may be interrupted and formed discontinuously over the trench TRCH, and an upper surface thereof may be formed continuously without interruption.

In embodiment 1 to embodiment 12, the end of the first emission component EU1 may be positioned on the first and second sidewalls S1 and S2 of the trench TRCH. The first emission component EU1 may also be positioned on the bottom surface BT of the trench TRCH.

Over the trench TRCH, the end of the first intermediate layer CGL1 according to each of embodiment 1 to embodiment 6 is positioned more distant from the bottom surface BT of the trench TRCH than is the end of the first intermediate layer CGL1 according to each of embodiment 7 to embodiment 12. As a result, it can be checked that the first intermediate layer CGL1 according to each of embodiment 7 to embodiment 12 that is incident on the pixel defining layer PDL at the second incident angle (or a high incident angle) may be formed deeper toward the first and second sidewalls S1 and S2 of the trench TRCH than is the first intermediate layer CGL1 according to each of embodiment 1 to embodiment 6 that is incident on the pixel defining layer PDL at the first incident angle (or a low incident angle).

Over the trench TRCH, the end of the second emission component EU2 according to each of embodiment 1 to embodiment 6 is positioned more distant from the bottom surface BT of the trench TRCH than is the end of the second emission component EU2 according to each of embodiment 7 to embodiment 12. As a result, it can be checked that the second emission component EU2 according to each of embodiment 7 to embodiment 12 that is incident on the first intermediate layer CGL1 at the second incident angle (or a high incident angle) may be formed deeper toward the first and second sidewalls S1 and S2 of the trench TRCH than is the second emission component EU2 according to each of embodiment 1 to embodiment 6 that is incident on the first intermediate layer CGL1 at the first incident angle (or a low incident angle).

Over the trench TRCH, the end of the second intermediate layer CGL2 according to each of embodiment 1 to embodiment 6 is positioned more distant from the bottom surface BT of the trench TRCH than is the end of the second intermediate layer CGL2 according to each of embodiment 7 to embodiment 12. As a result, it can be checked that the second intermediate layer CGL2 according to each of embodiment 7 to embodiment 12 that is incident on the second emission component EU2 at the second incident angle (or a high incident angle) may be formed deeper toward the first and second sidewalls S1 and S2 of the trench TRCH than is the second intermediate layer CGL2 according to each of embodiment 1 to embodiment 6 that is incident on the second emission component EU2 at the first incident angle (or a low incident angle).

Over the trench TRCH, a portion of the lower surface of the third emission component EU3 according to each of embodiment 1 to embodiment 12 is interrupted, and the upper surface thereof is not interrupted. As a result, over the trench TRCH, the third emission component EU3 according to each of embodiment 1to embodiment 12 may cover the end of the second intermediate layer CGL2 while mitigating step differences caused by the components disposed under the third emission component EU3.

In the aforementioned embodiments, in order to prevent or reduce the first intermediate layer CGL1 and the second intermediate layer CGL2 that include a material with a relatively high charge conductivity to have conductive properties from short-circuiting over the trench TRCH, each of the first and second intermediate layers CGL1 and CGL2 is incident on the pixel defining layer PDL at the first incident angle (or a low incident angle), taking into account the simulation result of FIG. 12. In some embodiments, the first to third emission components EU1, EU2, and EU3 that are disposed on the first and second intermediate layers CGL1 and CGL2 and include a material with a relatively low charge conductivity compared to the first and second intermediate layers CGL1 and CLG2 are incident on the pixel defining layer PDL at the second incident angle (or a high incident angle). In this case, the end EP2 (refer to FIG. 8) of the first intermediate layer CGL1 on the first and second sidewalls S1 and S2 of the trench TRCH may be positioned more distant from the bottom surface BT of the trench TRCH than is the end EP3 (refer to FIG. 8) of the second emission component EU2, and may be completely covered with the second emission component EU2. Furthermore, the end EP4 (refer to FIG. 8) of the second intermediate layer CGL2 on the first and second sidewalls S1 and S2 of the trench TRCH may be positioned more distant from the bottom surface BT of the trench TRCH than is the end EP5 (refer to FIG. 8) of the third emission component EU3, and may be completely covered with the third emission component EU3. As a result, the first intermediate layer CGL1 and the second intermediate layer CGL2 that have conductive properties may be prevented or protected from short-circuiting in the trench TRCH, whereby the sub-pixels can be operated with high reliability, thus improving the reliability of the display device DD (refer to FIG. 1).

Furthermore, in the aforementioned embodiments, the incident angles of the first and second intermediate layers CGL1 and CGL2 and the incident angles of the first to third emission components EU1, EU2, and EU3 may be controlled or selected by adjusting the inclination angles of the first and second angle-limit components AC1 and AC2 of the apparatus 1. Consequently, without performing a separate additional process, the first intermediate layer CGL1 and the second intermediate layer CGL2 that have conductive properties may be prevented or protected from short-circuiting by adjusting the incident angle of each of the first emission component EU1, the first intermediate layer CGL1, the second emission component EU2, the second intermediate layer CGL2, and the third emission component EU3. As a result, the fabrication efficiency of the display device may be further improved.

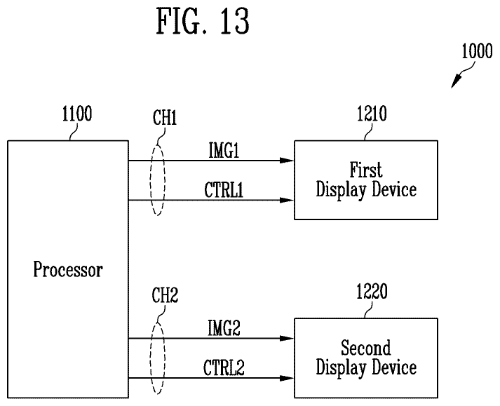

Hereinafter, an application field of the display device in accordance with one or more embodiments will be described with reference to FIGS. 13 to 15.

FIG. 13 is a schematic block diagram illustrating one or more embodiments of a display system 1000.

Referring to FIG. 13, the display system 1000 may include a processor 1100, and one or more display devices 1210 and 1220.

The processor 1100 may perform one or more suitable tasks and operations. In one or more embodiments, the processor 1100 may include an application processor, a graphic processor, a microprocessor, a central processing unit (CPU), and so on. The processor 1100 may be connected to the other components of the display system 1000 through a bus system to control the components.

In FIG. 13, there is illustrated the case where the display system 1000 includes the first and second display devices 1210 and 1220. The processor 1100 may be connected to the first display device 1210 through a first channel CH1, and may be connected to the second display device 1220 through a second channel CH2.

The processor 1100 may be to transmit first image data IMG1 and a first control signal CTRL1 to the first display device 1210 through the first channel CH1. The first display device 1210 may display an image based on the first image data IMG1 and the first control signal CTRL1. The first display device 1210 may have the same configuration as the display device DD described with reference to FIG. 1.

The processor 1100 may be to transmit second image data IMG2 and a second control signal CTRL2 to the second display device 1220 through the second channel CH2. The second display device 1220 may display an image based on the second image data IMG2 and the second control signal CTRL2. The second display device 1220 may have the same configuration as the display device DD described with reference to FIG. 1.

The display system 1000 may include computing systems that provide an image display function, such as a portable computer, a mobile phone, a smart phone, a tablet personal computer (tablet PC), a smart watch, a watch phone, a portable multimedia player, a navigation system, and/or an ultra-mobile personal computer (UMPC). Furthermore, the display system 1000 may include at least one of a head mounted display (HMD), a virtual reality (VR) device, a mixed reality (MR) device, and/or an augmented reality (AR) device.

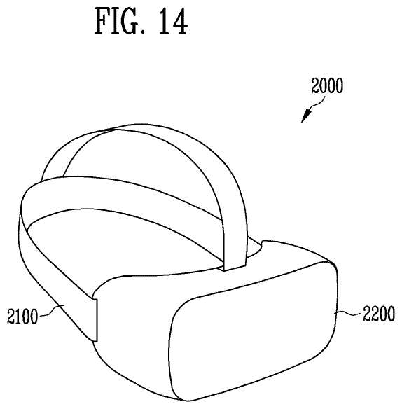

FIG. 14 is a schematic perspective view illustrating an application example of the display system of FIG. 13.

Referring to FIG. 14, the display system 1000 of FIG. 13 may be applied to a head mounted display 2000. The head mounted display 2000 may be a wearable electronic device, which can be worn on the head of the user.

The head mounted display 2000 may include a head mounted band 2100 and a display device reception casing 2200. The head mounted band 2100 may be connected to the display device reception casing 2200. The head mounted band 2100 may include a horizontal band and/or a vertical band to fasten the head mounted display 2000 to the head of the user. The horizontal band may enclose the sides of the head of the user, and the vertical band may enclose the top of the head of the user. However, the present disclosure is not limited to the aforementioned example. For example, the head mounted band 2100 may be implemented in the form of eyeglass frames, a helmet, and so on.

The display device reception casing 2200 may receive the first and second display devices 1210 and 1220 of FIG. 13. The display device reception casing 2200 may further receive the processor 1100 of FIG. 13.

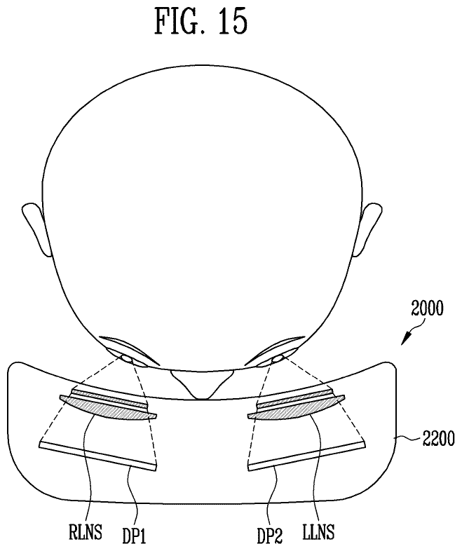

FIG. 15 is a schematic view illustrating the head mounted display of FIG. 14 that is worn on the user.

Referring to FIG. 15, the first display panel DP1 of the first display device 1210 (refer to FIG. 13) and the second display panel DP2 of the second display device 1220 (refer to FIG. 12) are disposed in the head mounted display 2000. The head mounted display 2000 may further include one or more lenses LLNS and RLNS.

In the display device reception casing 2200, a right-eye lens RLNS may be positioned between the first display panel DP1 and the right eye of the user. In the display device reception casing 2200, a left-eye lens LLNS may be positioned between the second display panel DP2 and the left eye of the user.

An image outputted from the first display panel DP1 can be viewed by the right eye of the user through the right-eye lens RLNS. The right lens RLNS may refract light emitted from the first display panel DP1 toward the right eye of the user. The right-eye lens RLNS may perform an optical function to adjust a viewing distance between the first display panel DP1 and the right eye of the user.

An image outputted from the second display panel DP2 can be viewed by the left eye of the user through the left-eye lens LLNS. The left lens LLNS may refract light emitted from the second display panel DP2 toward the left eye of the user. The left-eye lens LLNS may perform an optical function to adjust a viewing distance between the second display panel DP2 and the left eye of the user.

In one or more embodiments, each of the right-eye lens RLNS and the left-eye lens LLNS may include an optical lens having a pancake-shaped cross-section. In one or more embodiments, each of the right-eye lens RLNS and the left-eye lens LLNS may include a multi-channel lens including sub-areas having different optical characteristics. In this case, each display panel may output images respectively corresponding to sub-areas of the multi-channel lens. The output images may be viewed to the user through the corresponding sub-areas.

In accordance with one or more embodiment, incident angles (or deposition angles) of layers that form an emission structure disposed over a trench may differ from each other, so that short-circuit defects between layers including a material with a relatively high charge conductivity (or charge mobility) to have conductive properties from among the layers may be prevented or protected from occurring, whereby the reliability of the display device can be improved.

Furthermore, in accordance with one or more embodiments, an intermediate layer (or a charge generation layer) having conductive properties may be interrupted over the trench formed in a boundary area between adjacent sub-pixels. Consequently, leakage of current to adjacent sub-pixels through the intermediate layer may be reduced or prevented.

The effects, aspects, and features of embodiments of the present disclosure are not limited by the foregoing, and other one or more suitable effects, aspects, and features are anticipated herein.

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although specific embodiments and application examples have been described, it should be noted that other embodiments and modifications may be derived from the disclosure provided. Accordingly, the technical scope of the present disclosure is not limited to the foregoing embodiments, but rather to the broader scope of the appended claims, one or more suitable obvious modifications, and equivalent arrangements.

What is claimed is:

1. A display device, comprising:
a first sub-pixel; and
a second sub-pixel located adjacent to the first sub-pixel, wherein each of the first and the second sub-pixels comprises:
a first electrode;
a pixel defining layer on the first electrode;
a first emission component on the pixel defining layer and configured to emit light;
a first intermediate layer on the first emission component;
a second emission component on the first intermediate layer and configured to emit light; and
a second electrode on the second emission component,
wherein a trench is formed by recessing at least a portion of the pixel defining layer in a boundary area between the first sub-pixel and the second sub-pixel,
wherein the first intermediate layer is interrupted over the trench, and
wherein the second emission component completely covers the first intermediate layer over the trench.

2. The display device according to claim 1, wherein the first intermediate layer comprises a material having higher charge conductivity than that of each of the first and second emission components and has conductive properties.

3. The display device according to claim 2, wherein the first intermediate layer and the second electrode are electrically insulated from each other.

4. The display device according to claim 2,
wherein the pixel defining layer comprises a first surface and a second surface facing each other with the trench interposed therebetween, and a third surface connecting the first surface to the second surface, and
wherein the first surface comprises a first sidewall of the trench, the second surface comprises a second sidewall of the trench, and the third surface comprises a bottom surface of the trench.

5. The display device according to claim 4, wherein an end of the second emission component on the first and second sidewalls is closer to the bottom surface than is an end of the first intermediate layer to the bottom surface, and the second emission component completely covers the first intermediate layer on the first and second sidewalls.

6. The display device according to claim 4,
wherein the first emission component is interrupted in the trench, and
wherein the second emission component of the first sub-pixel and the second emission component of the second sub-pixel are connected to each other.

7. The display device according to claim 4, wherein each of the first and the second sub-pixels further comprises:
a third emission component located between the first electrode and the first emission component, and configured to emit light; and
a second intermediate layer located between the third emission component and the first emission component,
wherein the second intermediate layer is interrupted over the trench, and
wherein the first emission component completely covers the second intermediate layer over the trench.

8. The display device according to claim 7,
wherein the second intermediate layer comprises a material having higher charge conductivity than that of each of the first emission component, the second emission component, and the third emission component, and has conductive properties, and
wherein the first intermediate layer, the second intermediate layer, and the second electrode are electrically insulated from each other.

9. The display device according to claim 8,
wherein, on the first and the second sidewalls, an end of the second emission component is closer to the bottom surface than is an end of the first intermediate layer to the bottom surface, and an end of the first emission component is closer to the bottom surface than is an end of the second intermediate layer to the bottom surface, and
wherein, on the first and the second sidewalls, the second emission component completely covers the first intermediate layer, and the first emission component completely covers the second intermediate layer.

10. The display device according to claim 8,
wherein the third emission component and the first emission component are interrupted in the trench, and
wherein the second emission component of the first sub-pixel and the second emission component of the second sub-pixel are connected to each other.

11. The display device according to claim 8, wherein the trench comprises a void enclosed by the first emission component, the second emission component, and the third emission component.

12. The display device according to claim 8, wherein a distance between the first intermediate layer and the second electrode is greater than a distance between the first intermediate layer and the second intermediate layer.

13. The display device according to claim 7,
wherein the first emission component comprises a first hole transport component, a first emission layer, and a first electron transport component,
wherein the second emission component comprises a second hole transport component, a second emission layer, and a second electron transport component, and
wherein the third emission component comprises a third hole transport component, a third emission layer, and a third electron transport component.

14. An apparatus,
the apparatus being for fabricating a display device comprising a first sub-pixel and a second sub-pixel, each of the first sub-pixel and the second sub-pixel comprising a pixel defining layer, a first emission component, a first intermediate layer, a second emission component, and a second electrode that are successively located on a first electrode, and a trench formed by recessing a portion of the pixel defining layer in a boundary area between the first and the second sub-pixels, and
the apparatus comprising:
a first deposition chamber configured to form the first intermediate layer on the pixel defining layer; and
second deposition chamber configured to form each of the first and the second emission components on the pixel defining layer,
wherein the first deposition chamber comprises a first nozzle component configured to spray a deposition material of the first intermediate layer, and a first angle-limit component connected to the first nozzle component and configured to limit an incident angle of the deposition material,
wherein the second deposition chamber comprises a second nozzle component configured to spray deposition material of each of the first and the second emission components, and a second angle-limit component connected to the second nozzle component and configured to limit an incident angle of the deposition material, and
wherein the deposition material of the first intermediate layer and the deposition material of each of the first and the second emission components are incident on the pixel defining layer at different incident angles.

15. The apparatus according to claim 14, wherein the first intermediate layer comprises a material having higher charge conductivity than that of each of the first and second emission components and has conductive properties.

16. The apparatus according to claim 15,
wherein the first angle-limit component is configured to enable the deposition material of the first intermediate layer to be incident on the pixel defining layer at a low incident angle, and
wherein the second angle-limit component is configured to enable the deposition material of each of the first and second emission components to be incident on the pixel defining layer at a high incident angle.

17. The apparatus according to claim 15,
wherein each of the first and the second sub-pixels further comprises a second intermediate layer located between the second emission component and the second electrode and having conductive properties, and a third emission component located between the second intermediate layer and the second electrode, and
wherein the first deposition chamber is configured to spray deposition material of the second intermediate layer onto the second emission component, and the second deposition chamber is configured to spray deposition material of the third emission component onto the second intermediate layer.

18. The apparatus according to claim 17, wherein the deposition material of the second intermediate layer and the deposition material of the third emission component are to be incident at different incident angles.

19. A wearable electronic device comprising:
a display panel; and
a lens located on the display panel,
wherein the display panel comprises a first sub-pixel, and a second sub-pixel located adjacent to the first sub-pixel,
wherein each of the first and the second sub-pixels comprises:
a first electrode;
a pixel defining layer on the first electrode;
a first emission component on the pixel defining layer and configured to emit light;
a first intermediate layer on the first emission component;
a second emission component on the first intermediate layer and configured to emit light; and
a second electrode on the second emission component,
wherein a trench is formed by recessing at least a portion of the pixel defining layer in a boundary area between the first sub-pixel and the second sub-pixel,
wherein the first intermediate layer is interrupted over the trench, and
wherein the second emission component completely covers the first intermediate layer over the trench.

20. The wearable electronic device according to claim 19, wherein each of the first and the second sub-pixels comprises:
a third emission component between the first electrode and the first emission component, and configured to emit light; and
a second intermediate layer between the third emission component and the first emission component,
wherein the third emission component and the second intermediate layer are interrupted over the trench, and
wherein the first emission component completely covers the second intermediate layer over the trench.
